(19) United States
(12) Patent Application Publication
(10) Pub. No.: US 2024/0182782 A1
(43) Pub. Date: Jun. 6, 2024

(54) MATERIALS, PROCESS AND FABRICATION TECHNOLOGY FOR QUANTUM DOT COLOR CONVERSION FILTER BY SENSITIZED POLYMERIZATION

(71) Applicant: Sony Group Corporation, Tokyo (JP)

(72) Inventors: Hisaya HARA, Stuttgart (DE); Dennis CHERCKA, Stuttgart (DE); Clemens WALL, Stuttgart (DE); Nadejda KRASTEVA, Stuttgart (DE); Gabriele NELLES, Stuttgart (DE)

(73) Assignee: Sony Group Corporation, Tokyo (JP)

(21) Appl. No.: 18/284,328

(22) PCT Filed: Mar. 15, 2022
(86) PCT No.: PCT/EP2022/056725

§ 371 Date: Sep. 27, 2023

(30) Foreign Application Priority Data
Mar. 31, 2021 (EP) 21166310.9

(51) Int. Cl. C09K 11/06; C03C 17/00; C08K 3/30; C08K 3/38; C08K 5/56; C09K 11/02; G02B 5/22

(52) U.S. Cl. CPC C09K 11/06; C03C 17/007; C08K 3/30; C08K 3/38; C08K 5/56; C09K 11/02; G02B 5/223; C08K 2003/3027; C08K 2003/3036; C08K 2003/387

(57) ABSTRACT

The present disclosure relates to a composition comprising (i) a monomer, (ii) a photo initiator for photochemical polymerization of the monomer, (iii) a sensitizer, and (iv) quantum dots. The present disclosure further relates to a method for photochemical polymerization of quantum dot-based color conversion filter matrices and/or for matrix curing, comprising the use of a combination of a sensitizer and a photo initiator. The present disclosure also relates to thin layers and a quantum dot-based color conversion filter matrix comprising a thin layer. Moreover, the present disclosure relates to the use of a thin layer as quantum dot-based color conversion filter and to a device comprising a quantum dot-based color conversion filter.

### BACKGROUND

### Field of the Disclosure

The present disclosure relates to a composition comprising (i) a monomer, (ii) a photo initiator for photochemical polymerization of the monomer, (iii) a sensitizer, and (iv) quantum dots (QD). The present disclosure further relates to a method for photochemical polymerization of quantum dot-based color conversion filter (QD-CCF) matrices and/or for matrix curing, comprising the use of a combination of a sensitizer and a photo initiator. The present disclosure also relates to thin layers and a quantum dot-based color conversion filter (QD-CCF) matrix comprising a thin layer. Moreover, the present disclosure relates to the use of a thin layer as quantum dot-based color conversion filter (QD-CCF) and to a device comprising a quantum dot-based color conversion filter (QD-CCF).

### Description of the Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present disclosure.

Quantum-Dot Color Conversion Filters (QD-CCF) are rapidly becoming an industry standard for display applications as well as for lighting devices, such as micro LED displays, LED and LCD TVs, or LED lighting devices. Current research is focusing on the application of QD-CCFs as color conversion filters for e.g. micro-LED arrays and LED displays. In these applications, a blue emitting single LED or LED arrays are used as excitation light source for each display pixel. Color conversion to red and green is achieved by placing a color conversion layer comprising semiconductor quantum dots dispersed in a polymer matrix on top of the blue emitting LED.

Quantum dot color filters improve the color gamut of the devices such as displays, which results in a brighter output and improved efficiency. Providing quantum dot color conversion filters (QD-CCF) may involve a method of acrylate photopolymerization. However, a method involving acrylate photopolymerization is of limited use if high quantum dot loading in a film is required. A high load of quantum dots inhibits matrix curing. Furthermore, a high load of quantum dots results in inhomogeneous distribution and aggregation of quantum dots embedded in the polymer matrix.

### SUMMARY

In the following, the elements of the disclosure will be described. These elements are listed with specific embodiments, however, it should be understood that they may be combined in any manner and in any number to create additional embodiments. The variously described examples and preferred embodiments should not be construed to limit the present disclosure to only the explicitly described embodiments. This description should be understood to support and encompass embodiments which combine two or more of the explicitly described embodiments or which combine the one or more of the explicitly described embodiments with any number of the disclosed and/or preferred elements. Furthermore, any permutations and combinations of all described elements in this application should be considered disclosed by the description of the present application unless the context indicates otherwise.

The present disclosure provides a composition comprising
(i) a monomer,
(ii) a photo initiator for photochemical polymerization of the monomer,
(iii) a sensitizer, and
(iv) quantum dots (QD)
   for photochemical polymerization of quantum dot-based color conversion filter (QD-CCF) matrices and/or for matrix curing,
   wherein the monomer (i) is represented by formula I

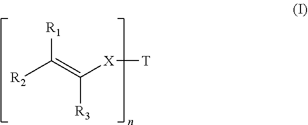

wherein
   R₁ to R₃ are of the same, or each is independently selected from hydrogen or a C₁ to C₂₀ alkyl group,
   T is selected from
a substituted or unsubstituted aliphatic hydrocarbon,
a substituted or unsubstituted aliphatic hydrocarbon wherein at least one methylene group is replaced with an ester group, an ether group, a carbonyl group, an amide group, or a combination thereof,
a substituted or unsubstituted alkylene oxide moiety, a substituted or unsubstituted polyalkylene oxide moiety,
a substituted or unsubstituted heterocyclic moiety,
a substituted or unsubstituted alicyclic moiety,
a substituted or unsubstituted aromatic hydrocarbon group,
an organic siloxane moiety,
or a combination thereof,
   X is an ester group (—C(═O)O—), a thiocarbonyl group (—S(═O)O—), an amide group (—C(═O)NH—), a carbonyl group, or a combination thereof,
   n is 1 to 4.

The present disclosure provides a method for photochemical polymerization of quantum dot-based color conversion filter (QD-CCF) matrices and/or for matrix curing,
comprising the use of a combination of a sensitizer and a photo initiator, and comprising the use of a composition of the present disclosure, or
   comprising the use of the components of the composition, in particular
the monomer (i) as defined in the present disclosure,
the photo initiator (ii) as defined in the present disclosure,
the sensitizer (iii) as defined in the present disclosure, and
the quantum dots (QDs) as defined in the present disclosure.

The present disclosure provides a thin layer, obtained with a method of the present disclosure.

The present disclosure provides a thin layer, obtained by using the composition of the present disclosure.

The present disclosure provides a quantum dot-based color conversion filter (QD-CCF) matrix, comprising a thin layer of the present disclosure.

The present disclosure provides a use of the thin layer of the present disclosure as a quantum dot-based color conversion filter (QD-CCF).

The present disclosure provides a device, comprising a quantum dot-based color conversion filter (QD-CCF), comprising a thin layer of the present disclosure, wherein said device is preferably a micro LED array display, a micro LED display, a LED backlight display, a LCD display, a LED device, or a LED lighting device.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 shows the working principle of an QD-CCF. Blue light emitted by LEDs is converted to red and green light components needed for a full color display by the QD-CCF layer. In the layer QDs are dispersed homogenously in a polymeric matrix.

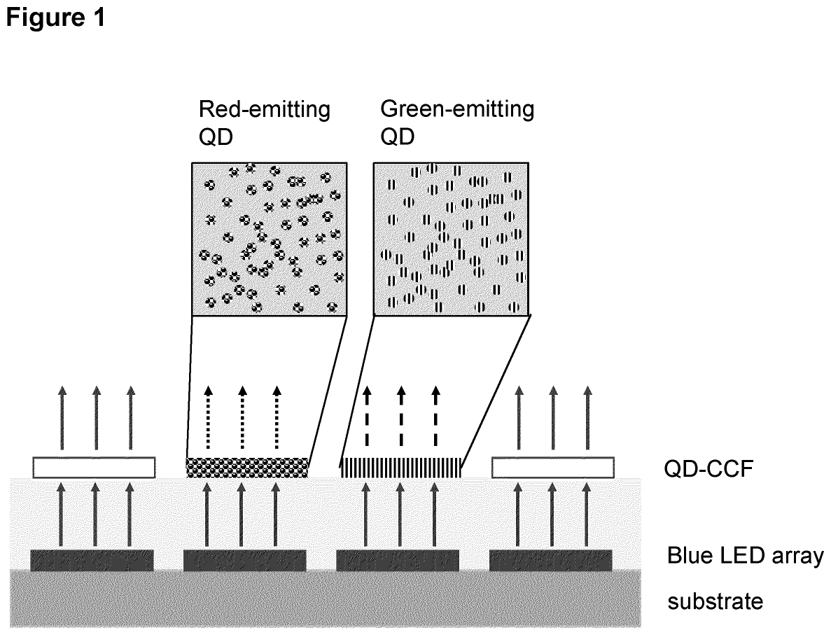

FIG. 2 shows absorbance of exemplary initiator, sensitizer, and quantum dots (QD). Typical radical initiators absorb in the blue or UV-region of the electromagnetic spectrum. In this spectral region, the QD absorption can be intense, especially in the case of high loading. Thus, the QDs absorb the photons intended for radical polymerization and matrix curing is inhibited. This may lead to the formation of only a thin cured skin on the film surface and unreacted monomers in a film bulk. Typically, the initiator loading is increased as a counter measure. This leads to additional sources for radical species in the film which can be detrimental to the long-time stability of the QD-CCF. Alternatively, initiators with absorption in the visible range may compromise the optical quality of the matrix. The polymer matrix ideally is transparent in the range from λ=380-800 nm. The light intended for matrix curing is absorbed by the sensitizer. The thus excited sensitizer molecule transfers the absorbed energy to the initiator. The initiator is in turn triggered to release a radical species used for matrix curing. In this case the sensitizer is chosen such that it absorbs light in a region of high transmittivity of the QDs. Using sensitized polymerization allows for a reliable initiation outside of the QD absorption region.

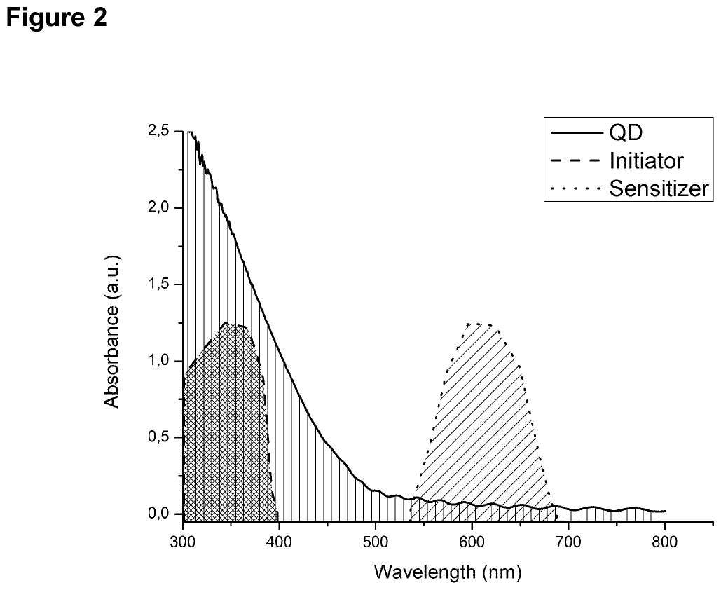

FIG. 3 shows exemplary initiators. Exemplary initiators are Ti-initiator, also referred to as bis(cyclopentadienyl)bis(2,6-difluoro-3-(1H-pyrro; 1-(2,4-Difluorophenyl)-1H-pyrrole titanium complex; P3B, also referred to as tetrabutylammonium-butyltriphenylborate; and N3B, also referred to as tetrabutylammonium-butyltrinaphthylborate.

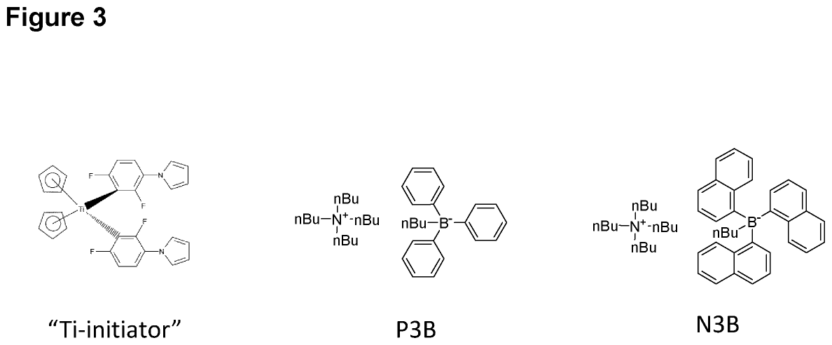

FIG. 4 shows exemplary sensitizers. Exemplary sensitizers are IRT, also referred to as 1-{2,2-bis[4-(diethylamino)phenyl]vinyl}-3,3-bis[4-(diethylamino)phenyl]propa-2-ene-1-ylium p-toluenesulfonate; methylene blue; merocyanines; and cyanines. The sensitizer may be chosen such that it absorbs light in a region of high transmittivity of the QDs.

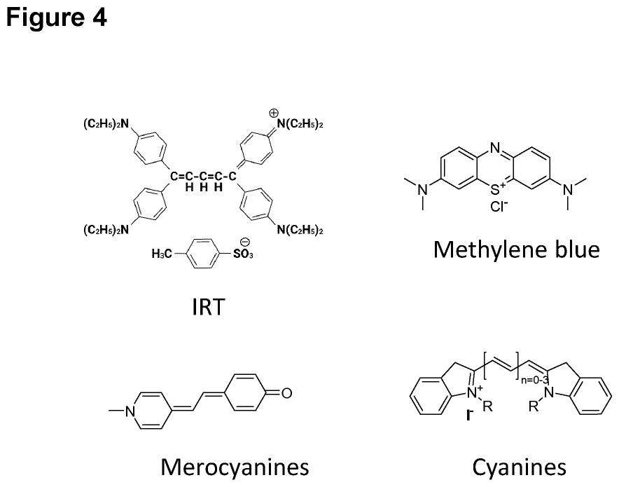

FIG. 5 shows exemplary monomers. Exemplary monomers are dicyclopentyldimethylene diacrylate (DDD); 1,12-dodecanediol dimethacrylate (A-DCP); and isostearyl acrylate (ISTA).

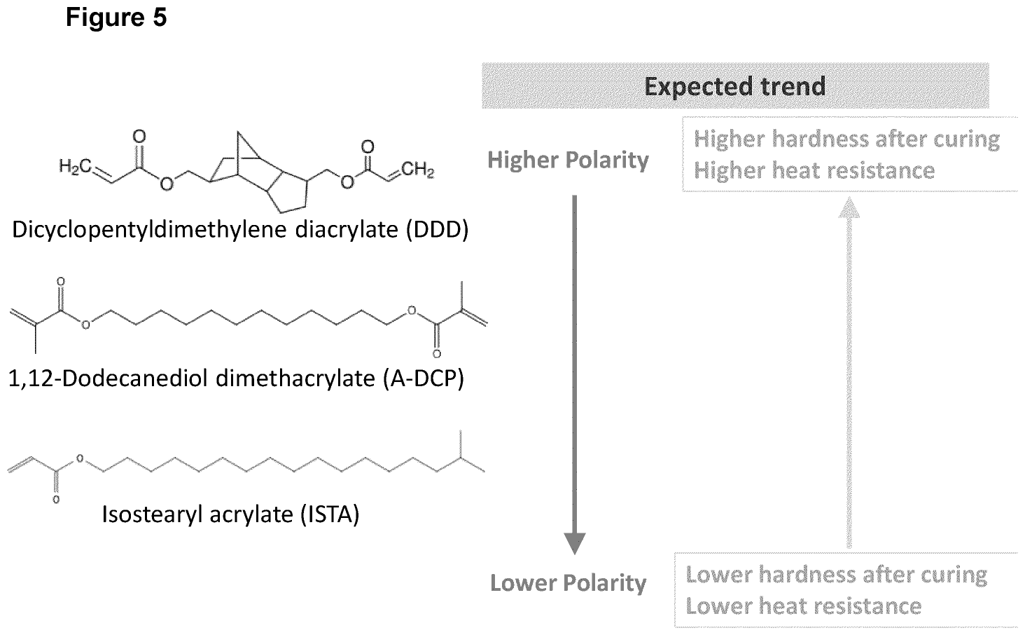

FIG. 6 shows an exemplary QD functionalization. Monomers are used as ligands of the QD. Particularly, the QD surface is functionalized with polymerizable ligands. Upon polymerization, the QD becomes a part of the polymer matrix.

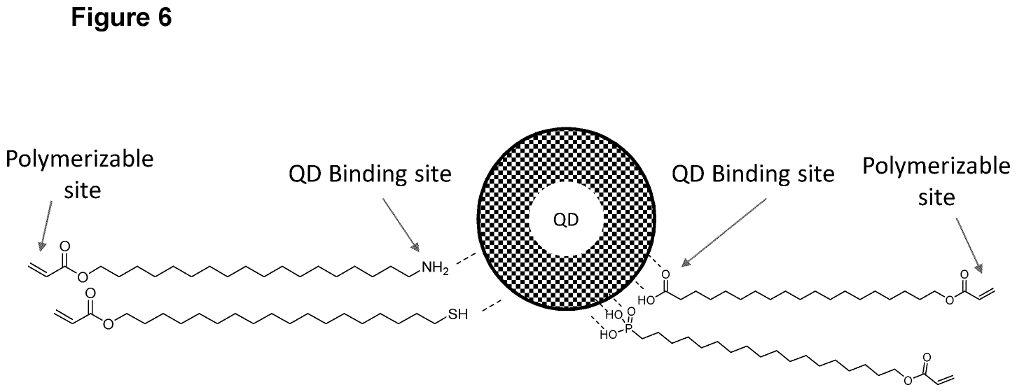

FIG. 7 shows exemplary polymerization tests with QDs. It was demonstrated that both exemplary photocatalytic systems work in the presence of 1 wt. % QDs. Decolorization and hardening were also confirmed. A A-DCP monomer/QD/photoinitator (Ti-Initiator 1.7 wt. % or N3B/IRT 0.06/0.08 wt. %) mixture was sealed between two glass plates and exposed to light (Ti-Initiator: Green LED, 40 mW/cm², 20 min; N3B/IRT: Red LED, 40 mw/cm², 10 min).

### DETAILED DESCRIPTION OF THE EMBODIMENTS

Referring now to the drawings, wherein like reference numerals designate identical or corresponding parts throughout the several views.

As discussed above, the present disclosure provides a composition comprising
a monomer,
(ii) a photo initiator for photochemical polymerization of the monomer,
(iii) a sensitizer, and
(iv) quantum dots (QD)
   for photochemical polymerization of quantum dot-based color conversion filter (QD-CCF) matrices and/or for matrix curing,
   wherein the monomer (i) is represented by formula I

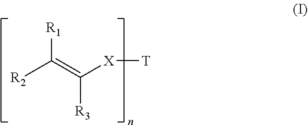

wherein
   R₁ to R₃ are of the same, or each is independently selected from hydrogen or a C₁ to C20 alkyl group,
   T is selected from
a substituted or unsubstituted aliphatic hydrocarbon,
a substituted or unsubstituted aliphatic hydrocarbon wherein at least one methylene group is replaced with an ester group, an ether group, a carbonyl group, an amide group, or a combination thereof,
a substituted or unsubstituted alkylene oxide moiety, a substituted or unsubstituted polyalkylene oxide moiety,
a substituted or unsubstituted heterocyclic moiety,
a substituted or unsubstituted alicylic moiety,
a substituted or unsubstituted aromatic hydrocarbon group,
an organic siloxane moiety,
or a combination thereof,
   X is an ester group (—C(═O)O—), a thiocarbonyl group (—S(═O)O—), an amide group (—C(═O)NH—), a carbonyl group, or a combination thereof,
   n is 1 to 4.

In one embodiment, the monomer (i) is represented by formulas Ia to Ic

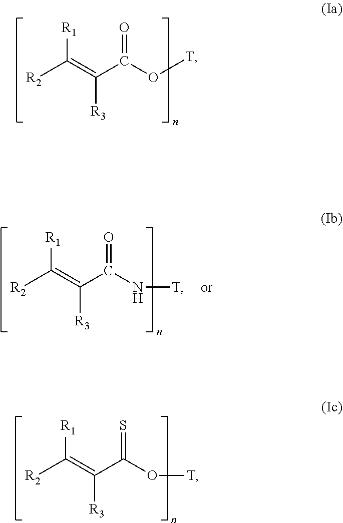

preferably Ia.

In one embodiment, the monomer (i) is selected from

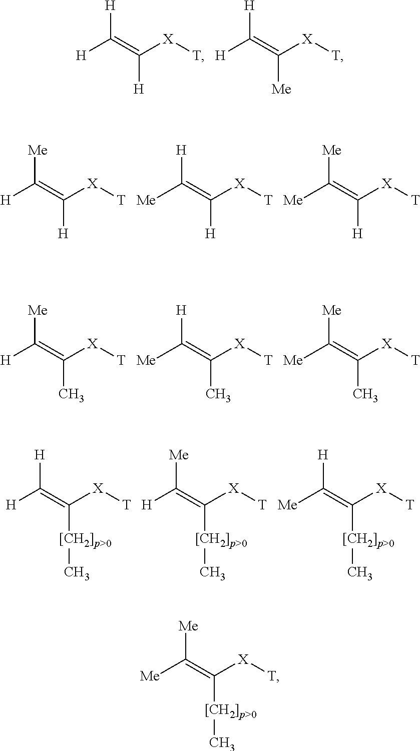

preferably

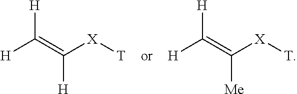

In one embodiment, X is a carbonyl group

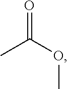

and the monomer (i) is a mono-functional monomer which is preferably selected from

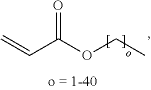

wherein o is 1 to 40, preferably 10 to 25, such as

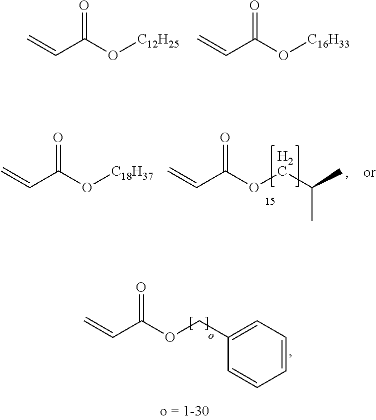

wherein o is 1 to 30, such as

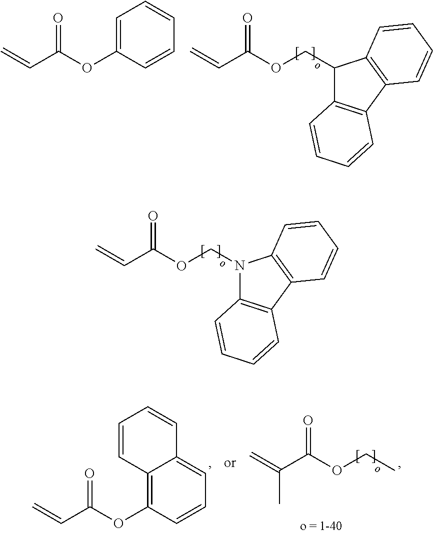

wherein o is 1 to 40, preferably 10 to 25, such as

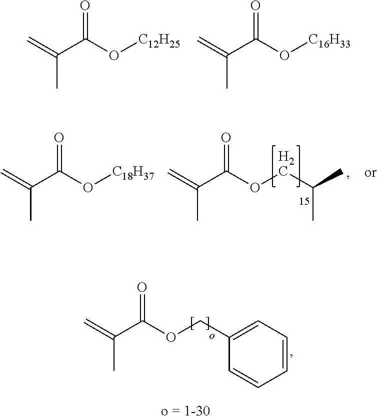

wherein o is 1 to 30, such as

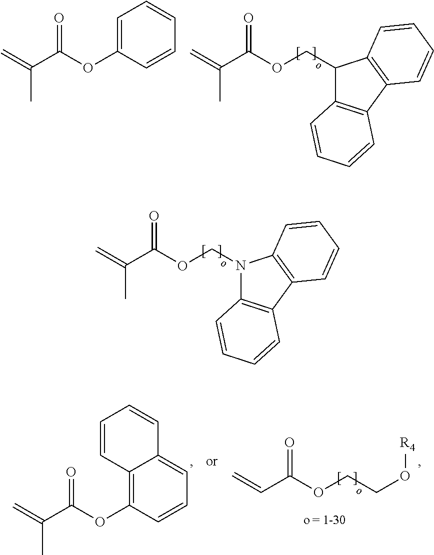

wherein o is 1 to 30 and R₄ is C₁ to C₁₀ alkylene group or C₁ to C₁₀-alkyl-phenylene group, such as

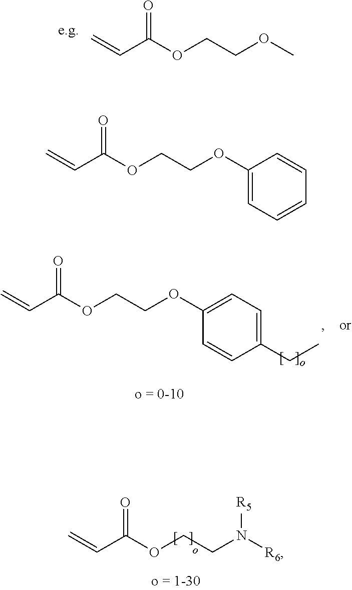

wherein o is 1 to 30 and R₅ and R₆ are the same or each independently selected from C₁ to C₁₀ alkylene group or can form a 6-membered ring, such as

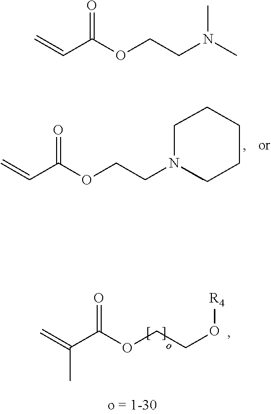

wherein o is 1 to 30 and R₄ is C₁ to C₁₀ alkylene group or C₁ to C₁₀-alkyl-phenylene group, such as

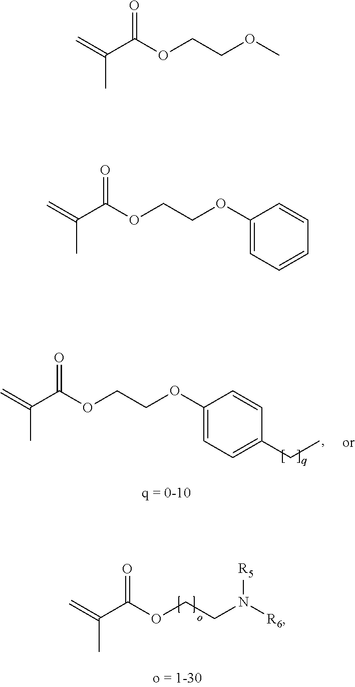

wherein o is 1 to 30 and R₅ and R₆ are the same or each independently selected from C₁ to C₁₀ alkylene group or can form a 6-membered ring, such as

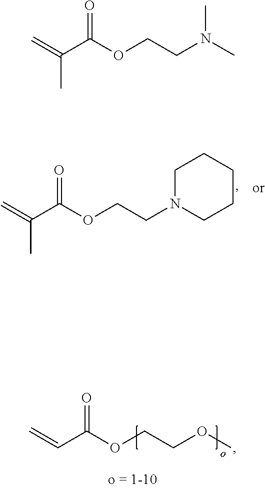

wherein o is 1 to 10, or

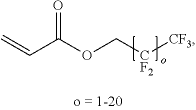

wherein o is 1 to 20, such as

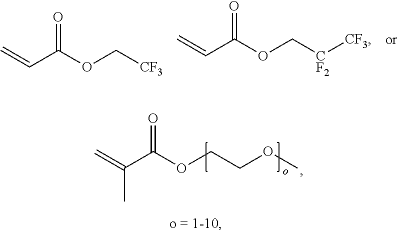

wherein o is 1 to 10, or

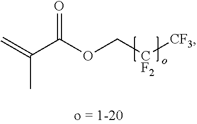

wherein o is 1 to 20, such as

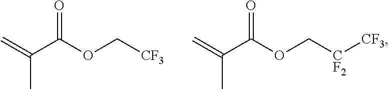

wherein the monomer is, for example, isostearyl acrylate (ISTA)

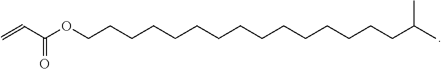 [SMILES: C=CC(=O)OCCCCCCCCCCCCCCCC(C)C]

In one embodiment, the monomer (i) is a poly-functional monomer which is preferably selected from

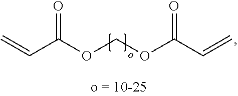

wherein o is 10 to 25, such as

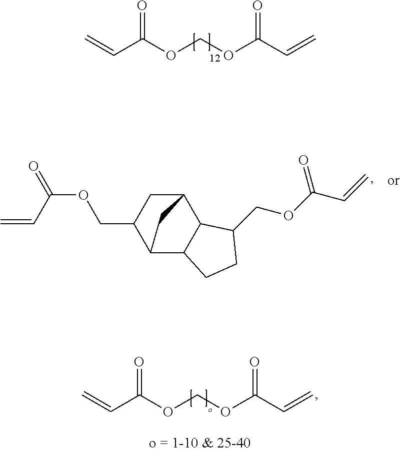

wherein o is 1 to 10 or 25 to 40, such as

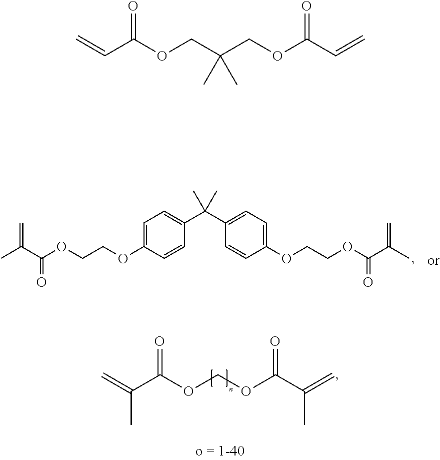

wherein o is 1 to 40, such as

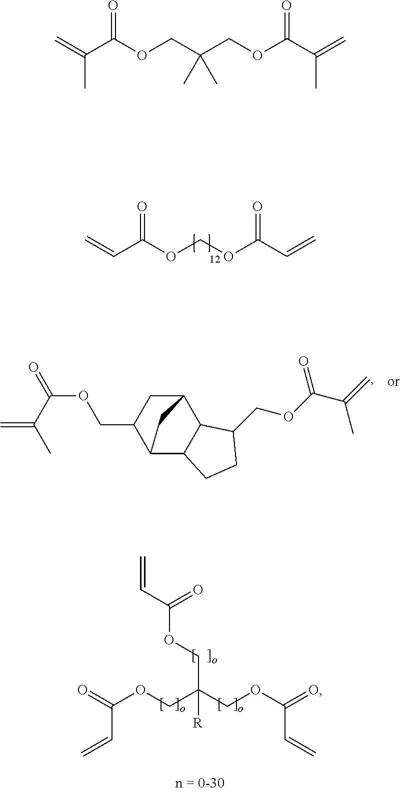

wherein o is 0 to 30, such as

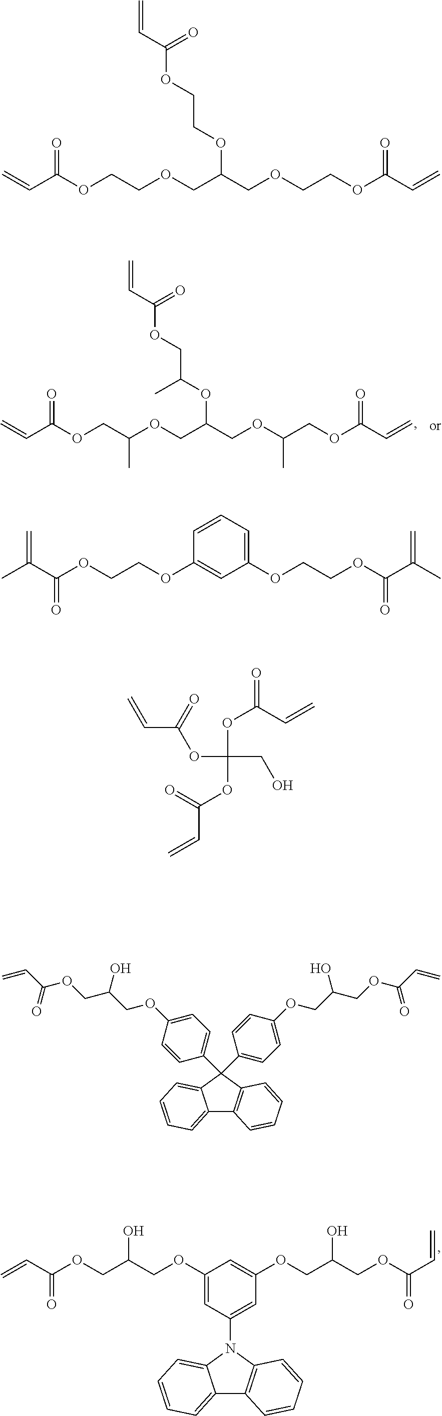

wherein the monomer is, for example, dicyclopentyldimethylene diacrylate (DDD)

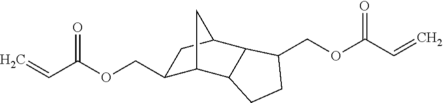 [SMILES: C=CC(=O)OCC1CC2CC1C1CCC(COC(=O)C=C)C21]

or 1,12-dodecanediol dimethacrylate (A-DCP)

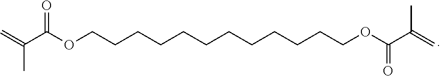 [SMILES: C=C(C)C(=O)OCCCCCCCCCCCCOC(=O)C(=C)C]

In one embodiment, the sensitizer (iii) absorbs light which is transferred to the photo initiator (ii),

wherein the sensitizer absorbs light preferably in a wavelength region of high transmittance of the QDs,
and/or the sensitizer is selected (iii) from 1-{2,2-Bis[4-(diethylamino)phenyl]vinyl}-3,3-bis[4-(diethylamino)phenyl]propa-2-ene-1-ylium p-toluenesulfonate (IRT), Methylene blue, a merocyanine or a cyanine.

In one embodiment, the photo initiator (ii) is Bis(cyclopentadienyl)bis(2,6-difluoro-3-(1H-pyrro; 1-(2,4-Difluorophenyl)-1H-pyrrole titanium complex (Ti-Initiator), Tetrabutylammonium-butyltrinaphthylborate (N3B) or Tetrabutylammonium-butyltriphenylborate (P3B).

In one embodiment, the quantum dots (QDs) (iv) comprise elements of several groups of the periodic system, such as but not limited to:
type II/VI semiconductor materials,
   such as CdS, CdSe, CdTe, ZnS, ZnSe, ZnTe, CdSe/ZnS, CdSe/CdS, CdSe/ZnSe, CdTe/CdS, CdTe/ZnS, CdTe/CdS/ZnS,
type III/V semiconductor materials,
   such as InP, InAs, GaAs,
group IV-VI elements,
   such as PbSe, PbS, PbTe,
group IB-(III)-VI elements,
   such as CuInS₂, AgInS₂, Ag₂Se, Ag₂S; CuInZnS/ZnS,
group IV elements,
   such as silicon QDs (Si QDs), carbon dots (C-dots), graphene QDs (GQDs).

In one embodiment, the quantum dots (iv) comprise polymerizable ligand(s) bound to their surface,

wherein a preferred polymerizable ligand is represented by formula II

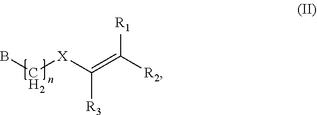

wherein
   B is a carboxylic acid group, amine group, thiol group, phosphonic acid group,
   X is ester group, a thiocarbonyl group, an amide group, or a combination thereof,
   n being at least 1, such as 1 to 30, preferably 10 to 20, such as

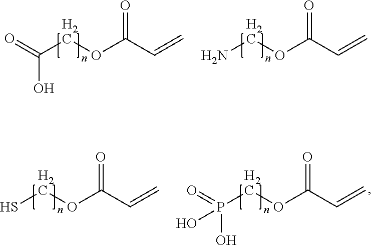

wherein said polymerizable ligand(s) are added during the polymerization or are a priori at the surface of the QDs.

As discussed above, the present disclosure provides a method for photochemical polymerization of quantum dot-based color conversion filter (QD-CCF) matrices and/or for matrix curing,
comprising the use of a combination of a sensitizer and a photo initiator, and comprising the use of a composition, as defined above, or
   comprising the use of the components of the composition, in particular
the monomer (i) as defined above,
the photo initiator (ii) as defined above,
the sensitizer (iii) as defined above, and
the quantum dots (QDs) as defined above.

In one embodiment, the method comprises the steps
(1) providing the monomer,
(2) adding the sensitizer and the photo initiator,
(3) adding the QDs, preferably as a dispersion.
(4) coating the mixture onto a substrate,
(5) exposing to light which is in the absorbance range of the sensitizer.

In one embodiment, after the addition of sensitizer and the photo initiator follows a heating step and the mixture is shielded from light.

In one embodiment, the method comprises thorough mixing after step (3).

In one embodiment, the method comprises the use of QDs having polymerizable ligand(s) bound to their surface, preferably as defined above.

In one embodiment, the method comprises the addition of polymerizable ligand(s) that bind to the surface of the QDs, wherein the polymerizable ligand(s) are preferably as defined above.

As discussed above, the present disclosure provides a thin layer, obtained with a method as defined above.

As discussed above, the present disclosure provides a thin layer, obtained by using the composition as defined above.

In one embodiment, the polymer is represented by formula III

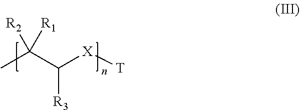

wherein
   R₁ to R₃, T and X are as defined above,
   n is equal to or greater than 2.

As discussed above, the present disclosure provides a quantum dot-based color conversion filter (QD-CCF) matrix, comprising a thin layer as defined above.

As discussed above, the present disclosure provides a use of the thin layer, as defined above, as quantum dot-based color conversion filter (QD-CCF).

As discussed above, the present disclosure provides a device, comprising a quantum dot-based color conversion filter (QD-CCF), comprising a thin layer as defined above, wherein said device is preferably a micro LED array display, a micro LED display, a LED backlight display, a LCD display, a LED device, or a LED lighting device.

When providing quantum-dot based color conversion filter (QD-CCF) matrices, acrylate photo polymerization is limited if high quantum dot loading in a film is required. Firstly, a high load of quantum dots inhibits matrix curing. Secondly, a high load of quantum dots results in inhomogeneous distribution of QDs and an aggregation of QDs within the polymer matrix. Thus, there is a need for efficient means for providing high quality quantum-dot based color conversion filter (QD-CCF) matrices, preferably having homogeneous distribution of QDs within the matrix and an absence of QD aggregation.

The present disclosure aims at addressing the problem of unreliable photo-polymerization of quantum-dot based color conversion filter (QD-CCF) matrix material. For example, the present disclosure aims at enhancing quantum dot distribution homogeneity within a matrix, for example of matrices with a high QD load. Furthermore, the present disclosure aims at preventing quantum dot aggregation within a matrix. The present disclosure also aims at providing transparent matrices, e.g. transparent thin layers, with high QD load. Furthermore, the present disclosure aims at providing a method involving polymerization which can be performed with visible light.

By utilizing a photosensitizer/initiator combination for the radical-promoted photo-polymerization of acrylates, the polymerization can be performed with visible light. The wavelength of the light can be chosen so that the photons are only weakly absorbed by the QD. This allows photo-chemical matrix curing even for high QD loaded matrices. Thus, superior QD-CCF, e.g. for the field of micro-LEDs, can be provided. Accordingly, the present disclosure provides enhanced means for polymerization of quantum-dot comprising matrices. The means of the disclosure are advantageous in that polymerization efficiency is increased. Furthermore, the means of the disclosure are advantageous in that polymerization can be performed with visible light. Furthermore, the means of the disclosure are advantageous in that photo-chemical matrix curing is effective even for matrices having a high QD load. The means of the disclosure are also advantageous in that superior QD-CCF can be provided. A method of the disclosure is highly advantageous in that films with high QD loading can be provided. In one embodiment, the term “means of the disclosure”, relates to a composition, method, thin layer, quantum dot-based color conversion filter (QD-CCF) matrix, quantum dot-based color conversion filter (QD-CCF), use, and/or device of the present disclosure.

The present disclosure further aims at preventing inhomogeneous distribution and aggregation of QDs within a polymer matrix. Such inhomogeneous distribution and aggregation of QDs within a matrix may, for example, occur when such QD/polymer materials are deposited on surfaces, e.g. to build a color conversion filter. In mechanically mixed systems of QDs and polymer, QDs may build large aggregates thus reducing both absorbance of the excitation light and photoluminescent emission efficiency of the color conversion filter. The present disclosure is advantageous in that using a photopolymerizable matrix reduces the aggregation tendency of QDs and improves the dispersability and homogeneity of QD distribution, e.g. in the resulting QD/polymer matrix film.

In one embodiment, a composition, method, thin layer, quantum dot-based color conversion filter (QD-CCF) matrix, quantum dot-based color conversion filter (QD-CCF), use, and/or device of the present disclosure are advantageous in that a homogeneous distribution of QDs is provided. Advantageously, an inhomogeneous distribution and/or aggregation of QDs embedded in a polymer matrix, e.g. a matrix of a thin layer, is/are prevented with the embodiments of the present disclosure.

In one embodiment, a composition, thin layer, quantum dot-based color conversion filter (QD-CCF) matrix, quantum dot-based color conversion filter (QD-CCF), and/or device of the present disclosure are implemented in a μLED array. In one embodiment, the present disclosure relates to a μLED array comprising a composition, thin layer, quantum dot-based color conversion filter (QD-CCF) matrix, quantum dot-based color conversion filter (QD-CCF), and/or device of the present disclosure. In one embodiment, a composition, thin layer, quantum dot-based color conversion filter (QD-CCF) matrix, quantum dot-based color conversion filter (QD-CCF), and/or device of the present disclosure is/are deposited on a surface, e.g. to produce a color conversion filter. In one embodiment, a method or use of the present disclosure comprise depositing a composition, thin layer, quantum dot-based color conversion filter (QD-CCF) matrix, quantum dot-based color conversion filter (QD-CCF), and/or device of the present disclosure on a surface. In one embodiment, thin layer, quantum dot-based color conversion filter (QD-CCF) matrix, and/or device of the present disclosure comprises or consists of a quantum dot-based color conversion filter (QD-CCF).

In one embodiment, the aim of the present disclosure is achieved using a sensitizer and initiator for the photochemical polymerization of QD-CCF matrices. In particular, the light intended for matrix curing is absorbed by the sensitizer. The thus excited sensitizer molecule transfers the absorbed energy to the initiator. The initiator is in turn triggered to release a radical species used for matrix curing. In a preferred embodiment, the sensitizer is selected such that it absorbs light in a region of high transmittivity of the QDs. In one embodiment, the sensitizer thus increases the polymerization efficiency. In one embodiment, the sensitizer allows for a polymerization with homogeneous QD distribution without QD aggregation.

Furthermore, the sensitizer and initiator used according to the present disclosure, e.g. in a method of the present disclosure, allow to provide a system, particularly a quantum dot-based color conversion filter (QD-CCF) matrix, which is transparent after polymer curing. Particularly, the composition of the present disclosure allows to provide a transparent quantum dot-based color conversion filter (QD-CCF) matrix, and a film thereof. In one embodiment, various acrylate monomers can be used in combination with the sensitizer and initiator combination, e.g. mono- and bifunctional alkyl and aryl acrylates, or methacrylates. In one embodiment, the sensitizer and initiator can be used in combination with any acrylate monomer. In one embodiment, the term “initiator” and “photo initiator” are used interchangeably.

In one embodiment, capping ligands are used for the QD, i.e. the QD comprises capping ligands and/or is configured to be bound by capping ligands. Such capping ligands are compatible with and can participate in the photoinitiated crosslinking of the polymer. In one embodiment, capping ligands significantly reduce the aggregation tendency of the QD in the polymer matrix. In one embodiment, a capping ligand comprises or consists of a monomer of the present disclosure. In one embodiment, a capping ligand is any of an acrylate monomer, mono- or bifunctional alkyl or aryl acrylate, or methacrylate monomer, or epoxy monomer. In one embodiment, a QD is functionalized with a capping ligand. In one embodiment, a capping ligand is attached to a QD. In one embodiment, the capping ligand is a polymerizable ligand. In one embodiment, the terms “capping ligand” and “polymerizable ligand” are used interchangeably.

The present disclosure is advantageous in that high QD loading in polymer films can be provided. Particularly, using a combination of sensitizer and photo initiator allows for effective polymerization of a matrix comprising QDs, particularly a high load of QDs. The present disclosure is further advantageous in that a wide variety of monomers can be used and thus allows polymer tuning for optimal dispersion of QDs in the matrix. The present disclosure is also advantageous in that a homogeneous distribution of QDs in the matrix is achieved. A further advantage of the present disclosure is that the matrix of highly QD-loaded films is reliably cured even in deep layers of the film. A further advantage of the present disclosure is that optical transparent films are achieved with matrix curing.

Further advantages of are as follows:

The sensitizer is decolored after polymerization resulting in a highly transparent polymer. The polymer matrix does not disrupt the color conversion process.

QDs do not absorb irradiation used for sensitized matrix polymerization. Accordingly, reliable matrix curing is possible even at high QD loading. QDs and the respective layer and/or device are not harmed by high intensity light used for sensitized matrix polymerization. In one embodiment, the terms “sensitized matrix polymerization” and “sensitized polymerization” relate to polymerization involving a sensitizer.

Large number of monomers are commercially available and matrix optimization to different QDs is possible, thus a cost effective solution is provided.

In one embodiment, a composition comprises one or more, preferably at least two, monomers to be polymerized. In one embodiment, a composition comprises one or more, e.g. two, types of monomers. In one embodiment, a monomer is a monofunctional, bifunctional, or polyfunctional monomer. In one embodiment, a polyfunctional monomer has the capacity to form chemical bonds to at least two other monomer molecules. In one embodiment, bifunctional monomers can form linear, chainlike polymers, and monomers of higher functionality yield cross-linked, network polymeric products. In one embodiment, a “monomer” is a monomer for a matrix, particularly a quantum dot-based color conversion filter (QD-CCF) matrix. In one embodiment, the monomer is represented by formula I

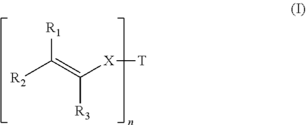

wherein
   R₁ to R₃ are of the same, or each is independently selected from hydrogen or a C₁ to C₂₀ alkyl group,
   T is selected from
a substituted or unsubstituted aliphatic hydrocarbon,
a substituted or unsubstituted aliphatic hydrocarbon wherein at least one methylene group is replaced with an ester group, an ether group, a carbonyl group, an amide group, or a combination thereof,
a substituted or unsubstituted alkylene oxide moiety, a substituted or unsubstituted polyalkylene oxide moiety,
a substituted or unsubstituted heterocyclic moiety,
a substituted or unsubstituted alicylic moiety,
a substituted or unsubstituted aromatic hydrocarbon group,
an organic siloxane moiety,
or a combination thereof,
   X is an ester group (—C(═O)O—), a thiocarbonyl group (—S(═O)O—), an amide group (—C(═O)NH—), a carbonyl group, or a combination thereof,
   n is 1 to 4.

In one embodiment, the monomer is represented by formulas Ia to Ic

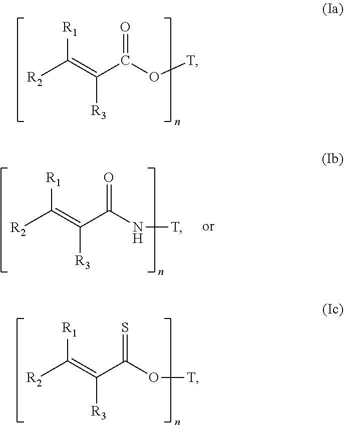

preferably Ia.

In a preferred embodiment, the monomer is isostearyl acrylate (ISTA)

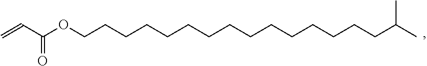 [SMILES: C=CC(=O)OCCCCCCCCCCCCCCCC(C)C]

dicyclopentyldimethylene diacrylate (DDD)

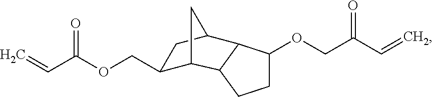 [SMILES: C=CC(=O)COC1CCC2C3CC(CC3COC(=O)C=C)C12]

or 1,12-dodecanediol dimethacrylate (A-DCP)

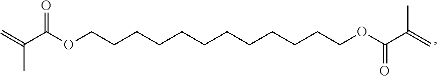 [SMILES: C=C(C)C(=O)OCCCCCCCCCCCCOC(=O)C(=C)C]

The term “photo initiator”, as used herein, relates to a molecule that creates reactive species, e.g. free radicals, cations or anions, when exposed to radiation. In one embodiment, the photo initiator is an initiator for photochemical polymerization of the monomer, preferably to provide a quantum dot-based color conversion filter (QD-CCF) matrix by photochemical polymerization. In one embodiment, the photo initiator (ii) is bis(cyclopentadienyl)bis(2,6-difluoro-3-(1H-pyrro; 1-(2,4-Difluorophenyl)-1H-pyrrole titanium complex (Ti-Initiator), Tetrabutylammonium-butyltrinaphthylborate (N3B), or Tetrabutylammonium-butyltriphenylborate (P3B).

The term “sensitizer”, as used herein, relates to a molecule which produces a physicochemical change in a neighboring molecule by either donating an electron to the substrate or by abstracting a hydrogen atom from the substrate. Particularly, sensitizers absorb electromagnetic radiation, e.g. infrared radiation, visible light radiation, and/or ultraviolet radiation, and transfer absorbed energy into neighboring molecules, e.g. into a photo initiator. In one embodiment, the sensitizer absorbs light which is transferred to the photo initiator. In one embodiment, the sensitizer is selected from 1-{2,2-Bis[4-(diethylamino)phenyl]vinyl}-3,3-bis[4-(diethylamino)phenyl]propa-2-ene-1-ylium p-toluenesulfonate (IRT), Methylene blue, a merocyanine, or a cyanine. In one embodiment, a sensitizer absorbs light having a wavelength in the range of 500 to 800 nm, preferably in the range of 550 to 650 nm.

The term “quantum dot” or “QD”, as used herein, relates to nanoscale materials, e.g. semiconductor materials, with highly tunable optical and electronic properties. In one embodiment, the quantum dots absorb at a wavelength of 390 nm to 1500 nm, preferably 400 nm to 1000 nm. In one embodiment, the quantum dots have a transmittance of at least 90% at a wavelength of 500 nm to 700 nm, preferably 550 nm to 650 nm. In one embodiment, a “high transmittance”, for example in the context of QDs, is at least 90%, preferably at least 99%. In one embodiment, QDs are any QDs known to the person skilled in the art. In one embodiment, QDs comprise elements of one or several groups of the periodic system, for example type II/VI semiconductor materials, such as CdS, CdSe, CdTe, ZnS, ZnSe, ZnTe, CdSe/ZnS, CdSe/CdS, CdSe/ZnSe, CdTe/CdS, CdTe/ZnS, CdTe/CdS/ZnS; type III/V semiconductor materials, such as InP, InAs, GaAs; group IV-VI elements, such as PbSe, PbS, PbTe; group IB-(III)-VI elements, such as CuInS₂, AgInS₂, Ag₂Se, Ag₂S, CuInZnS/ZnS; group IV elements, such as silicon QDs (Si QDs), carbon dots (C-dots), graphene QDs (GQDs). In one embodiment, a QD comprises any one of CdS, CdSe, CdTe, ZnS, ZnSe, ZnTe, CdSe/ZnS, CdSe/CdS, CdSe/ZnSe, CdTe/CdS, CdTe/ZnS, CdTe/CdS/ZnS, InP, InAs, GaAs, PbSe, PbS, PbTe, CuInS₂, AgInS₂, Ag₂Se, Ag₂S, CuInZnS/ZnS, silicon, carbon, graphene, or a combination thereof. In one embodiment, QDs comprise or consists of Cd-based (II/IV) and/or In-based (III/V) QD emitting in the visible spectrum, preferably in the range of from about 550 nm to about 630 nm. In one embodiment, a “high load” of QDs within a matrix, composition, mixture, layer, filter, and/or device is at least 1% vol, preferably at least 10% vol QDs, e.g. at least 1% vol, preferably at least 10% vol QDs with respect to a quantum dot-based color conversion filter (QD-CCF) matrix. Preferably, a “high load” of QDs within a matrix, composition, mixture, layer, filter, and/or device is 1% vol to 70% vol, preferably 10% vol to 50% vol. In one embodiment, the terms “filter”, “color conversion filter”, and “quantum dot-based color conversion filter” are used interchangeably.

The term “quantum dot-based color conversion filter (QD-CCF) matrices”, as used herein, relates to matrices, particularly polymer matrices, comprising quantum dots that are suitable for providing color conversion filters. In one embodiment, the matrices are subjected to photochemical polymerization. In one embodiment, the matrices comprise the monomer of the present disclosure. In one embodiment, the matrices comprise a polymer comprising the monomer of the present disclosure. In one embodiment, a matrix comprises a composition of the present disclosure.

In one embodiment, the polymer matrix is transparent in the range from λ=380-800 nm, e.g. in the range from λ=400-800 nm. In one embodiment, when referring to a “layer” or a “thin layer”, such layer has a thickness in the range of from 1 μm to 500 μm, preferably 5 μm to 100 μm. In one embodiment, the terms “film” and “layer” are used interchangeably. In one embodiment, a layer, preferably thin layer, is obtained by coating a composition and/or mixture comprising monomers, sensitizer, photo initiator, QDs, and optionally polymerizable ligands, onto a substrate. In one embodiment, such substrate is any suitable substrate, preferably transparent substrate, e.g. a substrate comprising or consisting of float glass, optical glass, sapphire glass, ITO glass, and/or organic polymer. In one embodiment, the device of the present disclosure comprises a thin layer of the present disclosure. In one embodiment, a thin layer comprises or consists of a quantum dot-based color conversion filter (QD-CCF) matrix. In one embodiment, a quantum dot-based color conversion filter (QD-CCF) comprises a thin layer of the present disclosure and/or a quantum dot-based color conversion filter (QD-CCF) matrix of the present disclosure. In one embodiment, a device of the present disclosure comprises a thin layer, a quantum dot-based color conversion filter (QD-CCF) matrix, and/or a quantum dot-based color conversion filter (QD-CCF) of the present disclosure.

In one embodiment, the term “alkyl” refers to a monovalent straight or branched chain, saturated aliphatic hydrocarbon radical having a number of carbon atoms in the specified range. Thus, for example, “C₁-C₆ alkyl” refers to any of the hexyl alkyl and pentyl alkyl isomers as well as n-, iso-, sec-, and t-butyl, n- and isopropyl, ethyl and methyl. Alkyl groups may be optionally substituted with one or more substituents with one or more substituents as defined herein. Alkyl groups may be straight or branched. Representative branched alkyl groups have one, two, or three branches. In one embodiment, “alkyl” refers to C₁, C₂, C₃, C₄, C₅, C₆, C₇, C₈, C₉, C₁₀, C₁₁, C₁₂, C₁₃, C₁₄, C₁₅, C₁₆ C₁₇, C₁₈, C₁₉, C₂₀, C₂₁, C₂₂, C₂₃ and/or C₂₄, alkyl, and combinations of any of the foregoing including the ranges C₁ to C₄, alkyl, C₂-C₄ alkyl, C₂-C₁₂ alkyl, C₃-C₆ alkyl, C₃-C₁₂ alkyl, C₄-C₆ alkyl, C₄-C₈ alkyl, C₄-C₁₀ alkyl, C₄-C₁₂ alkyl, C₅-C₈ alkyl, C₅-C₁₀ alkyl, C₅-C₁₂ alkyl, C₅-C₁₄ alkyl, C₆-C₈ alkyl, C₆-C₁₀ alkyl, C₆-C₁₂ alkyl.

The term “heterocyclic moiety” refers to any moiety which is a heterocycle, for example (i) optionally substituted 3- to 8-membered, e.g. 4- to 8-membered, saturated and unsaturated, non-aromatic or aromatic monocyclic rings containing at least one carbon atom and from 1 to 4 heteroatoms, (ii) optionally substituted bicyclic ring systems containing from 1 to 6 heteroatoms, and (iii) optionally substituted tricyclic ring systems, wherein each ring in (ii) or (iii) is independent of fused to, or bridged with the other ring or rings and each ring is saturated or unsaturated but nonaromatic, and wherein each heteroatom in (i), (ii), and (iii) is independently selected from N, O, and S, wherein each N is optionally in the form of an oxide and each S is optionally oxidized to S(O) or S(O)₂. Suitable 3- to 8-membered, e.g. 4- to 8-membered, saturated heterocycles include, for example, pyridinyl, carbazolyl, azetidinyl, piperidinyl, morpholinyl, thiomorpholinyl, thiazolidinyl, isothiazolidinyl, oxazolidinyl, isoxazolidinyl, pyrrolidinyl, imidazolidinyl, piperazinyl, tetrahydrofuranyl, tetrahydrothienyl, pyrazolidinyl, hexahydropyrimidinyl, thiazinanyl, thiazepanyl, azepanyl, diazepanyl, tetrahydropyranyl, tetrahydrothiopyranyl, dioxanyl, and azacyclooctyl. Suitable unsaturated heterocyclic rings include those corresponding to the saturated heterocyclic rings listed in the above sentence in which a single bond is replaced with a double bond. It is understood that the specific rings and ring systems suitable for use in the present disclosure are not limited to those listed in this and the preceding paragraphs. These rings and ring systems are merely representative.

In one embodiment, the term “hydrocarbon”, as used herein, relates to an aromatic or aliphatic hydrocarbon. In one embodiment, the aliphatic hydrocarbon is a saturated or unsaturated hydrocarbon. For example, exemplary aliphatic compounds may be n-, iso- and cyclo-alkanes (saturated hydrocarbons), and n-, iso- and cyclo-alkenes and -alkynes (unsaturated hydrocarbons). In one embodiment, a methylene group is any part of a molecule that consists of two hydrogen atoms bound to a carbon atom, which is connected to the remainder of the molecule by two single bonds. In one embodiment, an (poly)alkylene oxide moiety relates to 2-ethoxyethan-1-olyl, 2-(2-ethoxyethoxy)ethan-1-olyl or 2-(2-(2-ethoxyethoxy)ethoxy)ethan-1-olyl. In one embodiment, an alicyclic moiety contains one or more carbon rings which may be either saturated or unsaturated, but do not have aromatic character.

The term “substituted” indicates that a group, such as alkyl, a hydrocarbon, an alkylene oxide moiety, a polyalkylene oxide moiety, a heterocyclic moiety, an alicyclic moiety, or an aromatic hydrocarbon group, may be substituted with one or more substituents, such as substituted with one or more of C₁-C₁₀ alkyl, C₃-C₇ cycloalkyl, oxo, —OH, aryl, heteroaryl and heterocyclic. “Substituted” in reference to a group indicates that one or more hydrogen atoms attached to a member atom within the group is replaced with a substituent selected from the group of defined or suitable substituents. It should be understood that the term “substituted” includes the implicit provision that such substitution be in accordance with the permitted valence of the substituted atom and the substituent, and that the substitution results in a stable compound. When it is stated that a group may contain one or more substituents, one or more member atom within the group may be substituted. In addition, a single member atom within the group may be substituted with more than one substituent as long as such substitution is in accordance with the permitted valence of the atom.

The term “sensitizer absorbs light preferably in a wavelength region of high transmittance of the QDs”, as used herein, relates to a wavelength in the range of 500 -700 nm, preferably in the range of 550-650 nm.

The term “polymerizable ligand(s)”, as used herein, relates to ligands that have at least one polymerizable site and/or functional group. In one embodiment, polymerizable ligands may be polymerized to become part of a polymer matrix. A preferred polymerizable ligand is represented by formula II

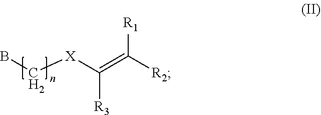

wherein
   B is a carboxylic acid group, amine group, thiol group, phosphonic acid group,
   X is ester group, a thiocarbonyl group, an amide group, or a combination thereof,
   n being at least 1, such as 1 to 30, preferably 10 to 20,
   such as

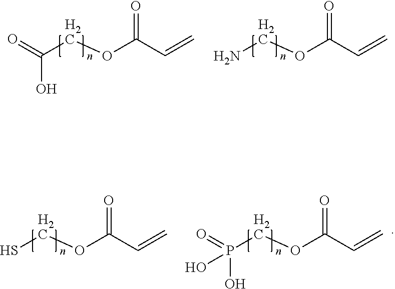

In one embodiment, a QD comprises one or more polymerizable ligands. In one embodiment, a QD comprises one or more polymerizable ligands attached to the surface of the QD. In one embodiment, a polymerizable ligand is coupled to a surface of the QD. In one embodiment, a polymerizable ligand is attached to the QD. In one embodiment, a polymerizable ligands is attached to a QD via a QD binding site. In one embodiment, a polymerizable ligands is attached to the QD prior to the QD being incorporated into a matrix. In an alternative embodiment, the polymerizable ligand is added to a matrix and attaches to the QD during polymerization of the matrix. In one embodiment, if polymerizable ligands are “a priori at the surface of the QDs”, such ligands are attached to the QD during production of the QD and/or are attached to the QD prior to the QD being incorporated into a matrix. In one embodiment, QDs have polymerizable ligand(s) bound to their surface. In one embodiment, the terms “bound to” and “attached to” are used interchangeably.

In one embodiment, steps (2) and (3) of a method of the present disclosure can be performed sequentially or simultaneously. In one embodiment, a method of the disclosure comprises i) providing the monomer, sensitizer, photo initiator, and the QDs, and optionally a solvent, ii) mixing the provided monomer, sensitizer, photo initiator, and the QDs, and iii) curing the mixture to obtain a matrix, e.g. by exposing the mixture to light which is in the absorbance range of the sensitizer. In one embodiment, the method comprises a step of coating the mixture onto a substrate to obtain a layer, preferably prior to said curing. In one embodiment, the terms “matrix”, “polymer matrix”, and “quantum dot-based color conversion filter (QD-CCF) matrix” are used interchangeably. In one embodiment, the method of the disclosure comprises adding a polymerizable ligand and/or adding QDs with a polymerizable ligand attached thereto. In one embodiment, in a method of the disclosure, a solvent comprised in a mixture is removed prior to a coating of the mixture and/or prior to a curing of the mixture. In one embodiment, a monomer, sensitizer, photo initiator, and/or the QDs are provided in the form of a mixture, e.g. dispersion, with a solvent. In one embodiment, the QDs are provided in the form of a dispersion of QDs and solvent. In one embodiment, the QDs are provided with a solvent.

The term “thorough mixing”, as used herein, relates to a thorough mixing to reach a homogeneous distribution of components within a mixture. In one embodiment, the term “thorough mixing” relates to a vigorous mixing. In one embodiment, the terms “thorough mixing” and “mixing” are used interchangeably.

In one embodiment, a “device” is any of a CLED device, e.g. CLED display, a μLED device, e.g. a μLED display such as a TV, a micro display, e.g. a micro display in a camera viewfinder, a VR wearable, xR wearable, AR wearable, and/or a LED lighting device, such as a chip LED or a LED array.

As used herein, the term “comprising” is to be construed as encompassing both “including” and “consisting of”, both meanings being specifically intended, and hence individually disclosed embodiments in accordance with the present disclosure. Where used herein, “and/or” is to be taken as specific disclosure of each of the two specified features or components with or without the other. For example, “A and/or B” is to be taken as specific disclosure of each of (i) A, (ii) B and (iii) A and B, just as if each is set out individually herein. In the context of the present disclosure, the terms “about” and “approximately” denote an interval of accuracy that the person skilled in the art will understand to still ensure the technical effect of the feature in question. Where an indefinite or definite article is used when referring to a singular noun, e.g. “a”, “an” or “the”, this includes a plural of that noun unless something else is specifically stated.

Note that the present technology can also be configured as described below.

(1) A composition comprising
(i) a monomer,
(ii) a photo initiator for photochemical polymerization of the monomer,
(iii) a sensitizer, and
(iv) quantum dots (QD)
   for photochemical polymerization of quantum dot-based color conversion filter (QD-CCF) matrices and/or for matrix curing,
   wherein the monomer (i) is represented by formula I

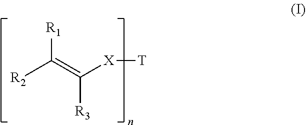

wherein
   R₁ to R₃ are of the same, or each is independently selected from hydrogen or a C₁ to C₂₀ alkyl group,
   T is selected from
a substituted or unsubstituted aliphatic hydrocarbon,
a substituted or unsubstituted aliphatic hydrocarbon wherein at least one methylene group is replaced with an ester group, an ether group, a carbonyl group, an amide group, or a combination thereof,
a substituted or unsubstituted alkylene oxide moiety, a substituted or unsubstituted polyalkylene oxide moiety,
a substituted or unsubstituted heterocyclic moiety,
a substituted or unsubstituted alicylic moiety,
a substituted or unsubstituted aromatic hydrocarbon group,
an organic siloxane moiety,
or a combination thereof,
   X is an ester group (—C(═O)O—), a thiocarbonyl group (—S(═O)O—), an amide group (—C(═O)NH—), a carbonyl group, or a combination thereof,
   n is 1 to 4.
   (2) The composition of embodiment (1), wherein the monomer (i) is represented by formulas Ia to Ic

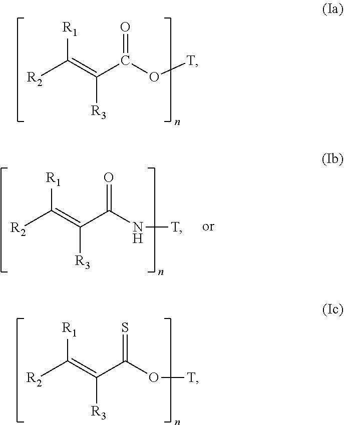

preferably Ia.
(3) The composition of embodiment (1) or (2), wherein the monomer (i) is selected from

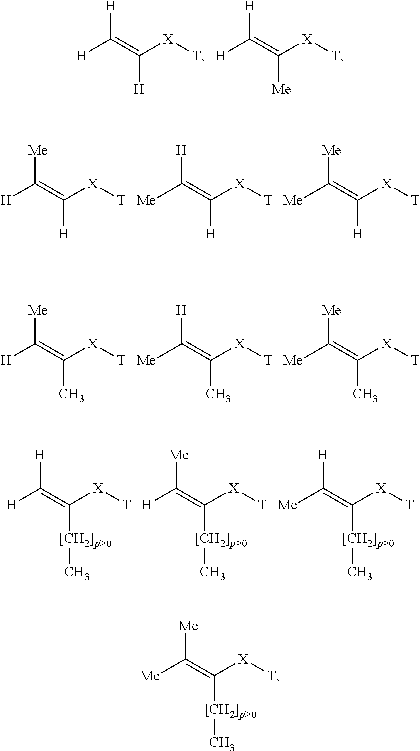

preferably

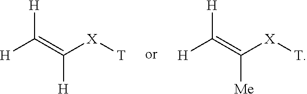

(4) The composition of any one of embodiments (1) to (3), wherein X is a carbonyl group

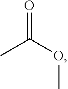

and the monomer (i) is a mono-functional monomer which is preferably selected from

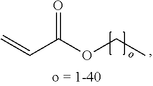

wherein o is 1 to 40, preferably 10 to 25, such as

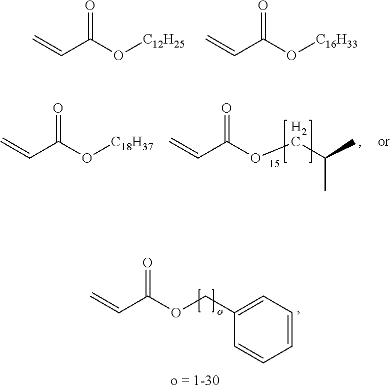

wherein o is 1 to 30, such as

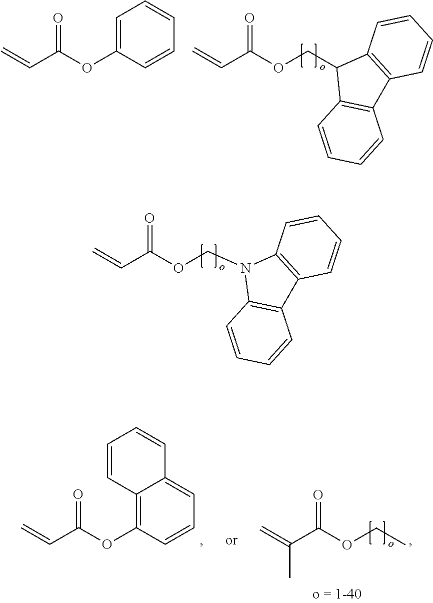

wherein o is 1 to 40, preferably 10 to 25, such as

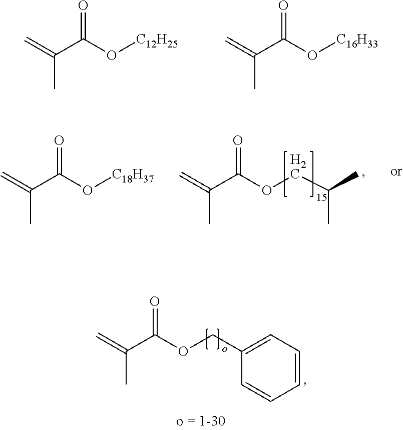

wherein o is 1 to 30, such as

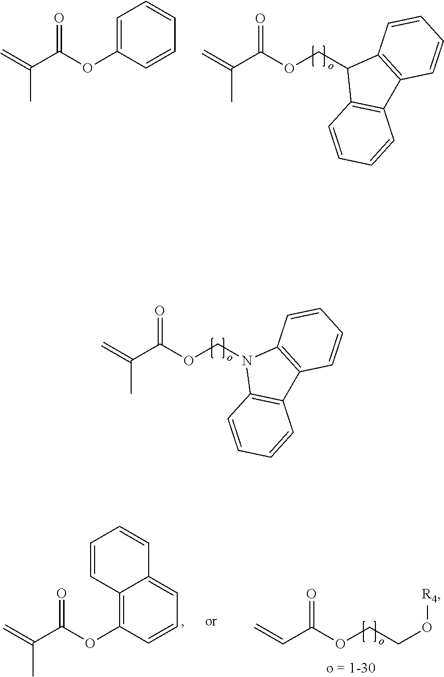

wherein o is 1 to 30 and R₄ is C₁ to C₁₀ alkylene group or C₁ to C₁₀-alkyl-phenylene group, such as

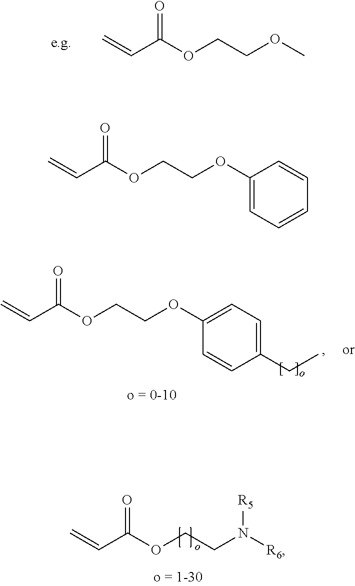

wherein o is 1 to 30 and R₅ and R₆ are the same or each independently selected from C₁ to C₁₀ alkylene group or can form a 6-membered ring, such as

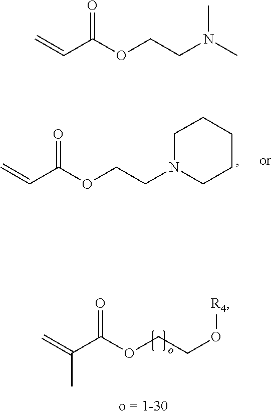

wherein o is 1 to 30 and R₄ is C₁ to C₁₀ alkylene group or C₁ to C₁₀-alkyl-phenylene group, such as

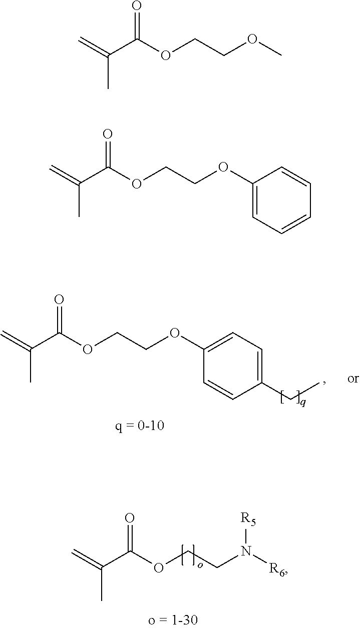

wherein o is 1 to 30 and R₅ and R₆ are the same or each independently selected from C₁ to C₁₀ alkylene group or can form a 6-membered ring, such as

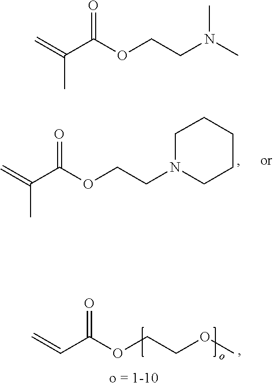

wherein o is 1 to 10, or

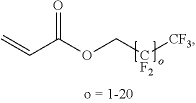

wherein o is 1 to 20, such as

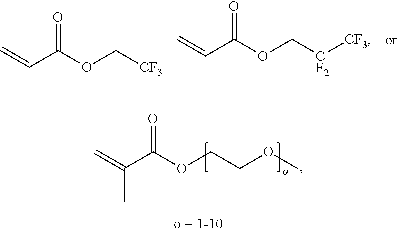

wherein o is 1 to 10, or

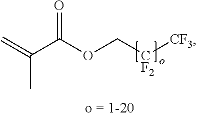

wherein o is 1 to 20, such as

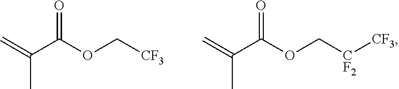

wherein the monomer is, for example, isostearyl acrylate (ISTA)

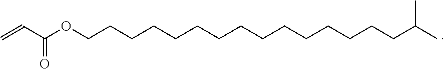 [SMILES: C=CC(=O)OCCCCCCCCCCCCCCCC(C)C]

(5) The composition of any one of embodiments (1) to (3), wherein the monomer (i) is a poly-functional monomer which is preferably selected from

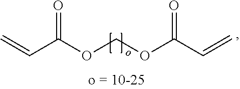

wherein o is 10 to 25, such as

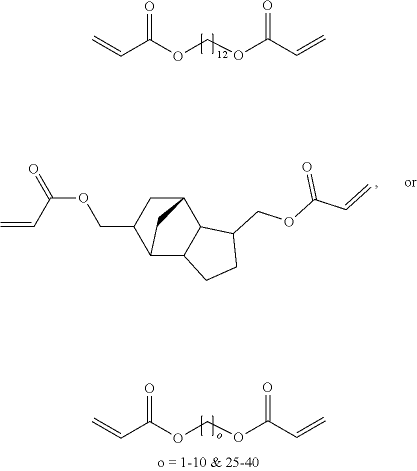

wherein o is 1 to 10 or 25 to 40, such as

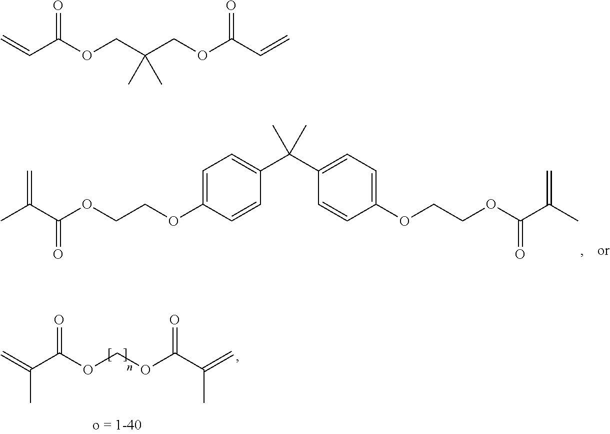

wherein o is 1 to 40, such as

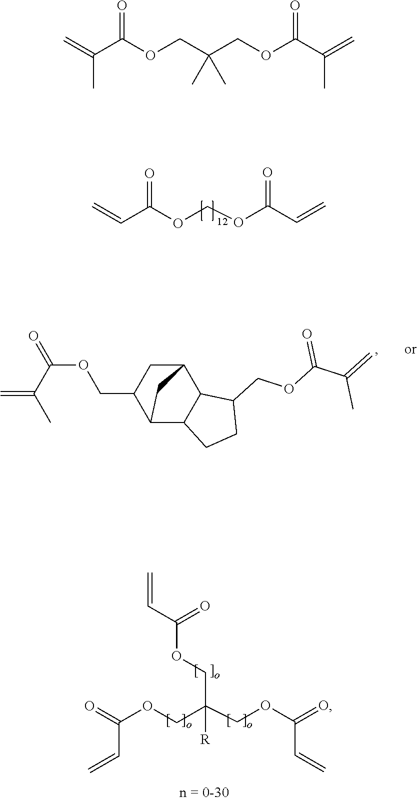

wherein o is 0 to 30, such as

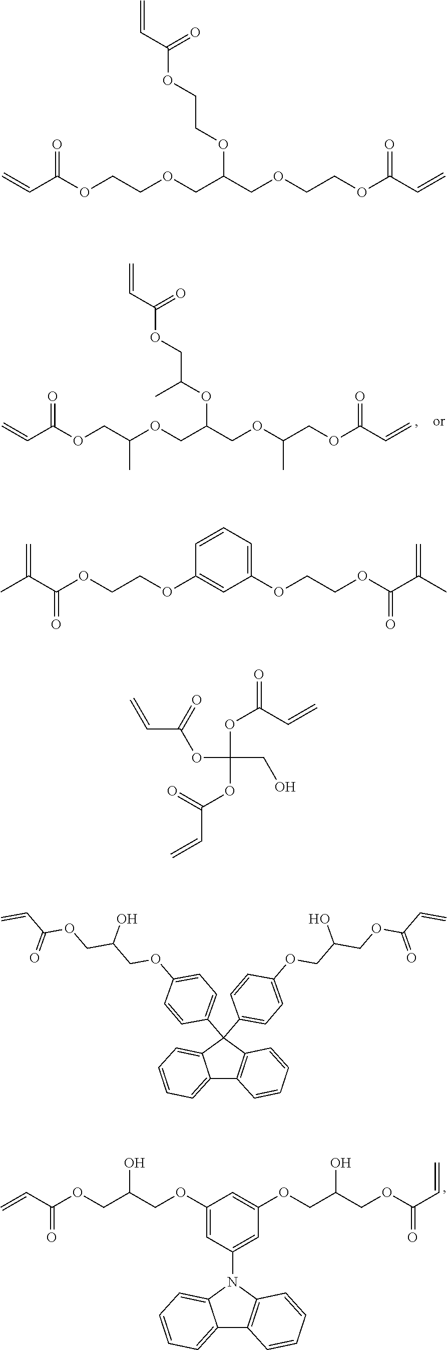

wherein the monomer is, for example, dicyclopentyldimethylene diacrylate (DDD)

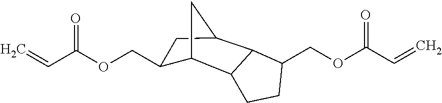 [SMILES: C=CC(=O)OCC1CC2CC1C1CCC(COC(=O)C=C)C21]

or 1,12-dodecanediol dimethacrylate (A-DCP)

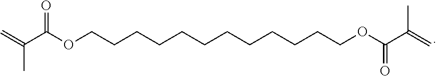 [SMILES: C=C(C)C(=O)OCCCCCCCCCCCCOC(=O)C(=C)C]

(6) The composition of any one of embodiments (1) to (5), wherein the sensitizer (iii) absorbs light which is transferred to the photo initiator (ii),
wherein the sensitizer absorbs light preferably in a wavelength region of high transmittance of the QDs,
and/or wherein the sensitizer is selected (iii) from 1-{2,2-Bis[4-(diethylamino)phenyl]vinyl}-3,3-bis[4-(diethylamino)phenyl]propa-2-ene-1-ylium p-toluenesulfonate (IRT), Methylene blue, a merocyanine or a cyanine.
(7) The composition of any one of embodiments (1) to (6), wherein the photo initiator (ii) is Bis(cyclopentadienyl)bis(2,6-difluoro-3-(1H-pyrro; 1-(2,4-Difluorophenyl)-1H-pyrrole titanium complex (Ti-Initiator), Tetrabutylammonium-butyltrinaphthylborate (N3B) or Tetrabutylammonium-butyltriphenylborate (P3B).
(8) The composition of any one of embodiments (1) to (7), wherein the quantum dots (QDs) (iv) comprise elements of several groups of the periodic system, such as but not limited to:
type II/VI semiconductor materials,
   such as CdS, CdSe, CdTe, ZnS, ZnSe, ZnTe, CdSe/ZnS, CdSe/CdS, CdSe/ZnSe, CdTe/CdS, CdTe/ZnS, CdTe/CdS/ZnS,
type III/V semiconductor materials,
   such as InP, InAs, GaAs,
group IV-VI elements,
   such as PbSe, PbS, PbTe,
group IB-(III)-VI elements,
   such as CuInS₂, AgInS₂, Ag₂Se, Ag₂S; CuInZnS/ZnS,
group IV elements,
   such as silicon QDs (Si QDs), carbon dots (C-dots), graphene QDs (GQDs).
      (9) The composition of any one of embodiments (1) to (8), wherein the quantum dots (iv) comprise polymerizable ligand(s) bound to their surface,
      wherein a preferred polymerizable ligand is represented by formula II

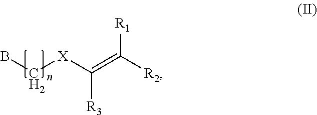

wherein
   B is a carboxylic acid group, amine group, thiol group, phosphonic acid group,
   X is ester group, a thiocarbonyl group, an amide group, or a combination thereof,
   n being at least 1, such as 1 to 30, preferably 10 to 20, such as

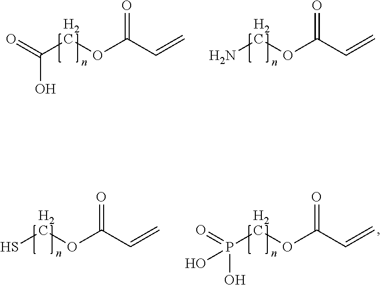

wherein said polymerizable ligand(s) are added during the polymerization or are a priori at the surface of the QDs.
(10) A method for photochemical polymerization of quantum dot-based color conversion filter (QD-CCF) matrices and/or for matrix curing,
comprising the use of a combination of a sensitizer and a photo initiator, and comprising the use of a composition of any one of embodiments (1) to (8), or comprising the use of the components of the composition, in particular
the monomer (i) as defined in any one of embodiments (1) to (5),
the photo initiator (ii) is as defined in embodiment (7),
the sensitizer (iii) is as defined in embodiment (6), and
the quantum dots (QDs) are as defined in embodiment (8).
   (11) The method of embodiment (10), comprising the steps
(1) providing the monomer,
(2) adding the sensitizer and the photo initiator,
(3) adding the QDs, preferably as a dispersion.
(4) coating the mixture onto a substrate,
(5) exposing to light which is in the absorbance range of the sensitizer.
   (12) The method of embodiment (11), wherein after the addition of sensitizer and the photo initiator follows a heating step and the mixture is shielded from light.
   (13) The method of embodiment (11) or (12), comprising thorough mixing after step (3).
   (14) The method of any one of embodiments (10) to (13), comprising the use of QDs having polymerizable ligand(s) bound to their surface, preferably as defined in embodiment (9).
   (15) The method of any one of embodiments (10) to (14), comprising the addition of polymerizable ligand(s) that bind to the surface of the QDs, wherein the polymerizable ligand(s) are preferably as defined in embodiment (9).
   (16) A thin layer, obtained with a method according to any one of embodiments (10) to (15).
   (17) A thin layer, obtained by using the composition of any one of embodiments (1) to (9).
   (18) The thin layer of embodiment (16) or (17), wherein the polymer is represented by formula III

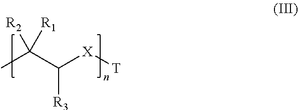

wherein
   R₁ to R₃, T and X are as defined in embodiment (1),
   n is equal to or greater than 2.
   (19) A quantum dot-based color conversion filter (QD-CCF) matrix, comprising a thin layer of any one of embodiments (16) to (18).
   (20) Use of the thin layer of any one of embodiments (16) to (18) as quantum dot-based color conversion filter (QD-CCF).
   (21) A device, comprising a quantum dot-based color conversion filter (QD-CCF), comprising a thin layer of any one of embodiments (16) to (18), wherein said device is preferably a micro LED array display, a micro LED display, a LED backlight display, a LCD display, a LED device, or a LED lighting device.

The features of the present disclosure disclosed in the specification, the claims, and/or in the accompanying figures may, both separately and in any combination thereof, be material for realizing the disclosure in various forms thereof.

Thus, the foregoing discussion discloses and describes merely exemplary embodiments of the present disclosure. As will be understood by those skilled in the art, the present disclosure may be embodied in other specific forms without departing from the spirit or essential characteristics thereof. Accordingly, the disclosure of the present disclosure is intended to be illustrative, but not limiting of the scope of the disclosure, as well as other claims. The disclosure, including any readily discernible variants of the teachings herein, define, in part, the scope of the foregoing claim terminology such that no inventive subject matter is dedicated to the public.

### EXAMPLES

### Example 1: Polymerization and Exemplary Production of a Film

CdSe/CdS based quantum dots (QD) were used as QD, isostearyl acrylate (ISTA) was used as monomer, and (di-eta(5)-cyclopentadienyl)-bis[2,6-difluoro-3-(pyrrol-1-yl)-phenyl]titanium(IV) (Ti-initiator) was used as initiator.

The exemplary radically polymerizable monomer (isostearyl acrylate (ISTA), 1.00 g) was loaded into a brown vial, mixed with the Ti-initiator and the vial was shielded from light with aluminum foil. The mixture was heated at 65° C. for 0.5-1.5 h to dissolve the initiator in the monomer.

Under inert atmosphere, a 300 μl quantum dot dispersion (10 mg/ml in hexane) was mixed with 344 μl monomer/photocatalyst mixture. The solvent was removed under reduced pressure. For producing a film, the QD/monomer/initiator mixture was coated onto a glass substrate and exposed to green light (524 nm) of 40 mW/cm² for 20 min. The sample polymerized to give a solidified film. Furthermore, the color-shade associated with the initiator faded resulting in the pure QD absorption. A quantum dot-based color conversion filter (QD-CCF) matrix layer with homogeneous distribution of QDs was successfully achieved.

### Example 2: Polymerization and Exemplary Production of a Film

CdSe/CdS based quantum dots (QD) were used as QD, dicyclopentyldimethylene diacrylate (A-DCP) was used as monomer, tetrabutylammonium butyltrinaphthylborate (N3B) was used as initiator, and 1,1,5,5-Tetrakis[4-(diethylamino)phenyl]-1,4-pentadiene-3-ylium p-toluenesulfonate (IRT) was used as sensitizer.

The exemplary radically polymerizable monomer (dicyclopentyldimethylene diacrylate (A-DCP), 4.00 g) was loaded into a brown vial; N3B (0.0024 g) and IRT (0.0032 g) were added, and the vial was shielded from light with aluminum foil. The mixture was heated at 65° C. for 0.5-1.5 h to dissolve N3B and IRT in the monomer.

Under inert atmosphere, a 300 μl quantum dot dispersion (10 mg/ml in hexane) was mixed with 273 μl monomer/photocatalyst mixture. The solvent was removed under reduced pressure. For producing a film, the QD/monomer/initiator mixture was coated onto a glass substrate and exposed to red light (640 nm) of 40 mW/cm² for 10 min. The sample polymerized to give a hard film. Furthermore, the color-shade associated with the sensitizer faded resulting in the pure QD absorption. A quantum dot-based color conversion filter (QD-CCF) matrix layer with homogeneous distribution of QDs was successfully achieved.

### Example 3: Polymerization and Exemplary Production of a Film

A-DCP is mixed with alkyl substituted Quantum dots (1-100 mg/ml) in CHCl₃. N3B (0.01-1%) and IRT (0.01-1%) were added to the mixture. The solvent was removed under reduced pressure and the resulting dispersion dropcasted onto a glass substrate. The sample was covered with a second substrate and cured by exposure to red light (λₘₐₓ=650 nm) for a period of time (1-60 min). The sample polymerized to give a solidified film. Furthermore, the color-shade associated with the sensitizer faded resulting in the pure QD absorption. A quantum dot-based color conversion filter (QD-CCF) matrix layer with homogeneous distribution of QDs was successfully achieved.

### Example 4: Exemplary Polymerization Tests With QDs

### Sample Conditions:

Crystalplex QDs (CdSxSel-x/ZnS, TriLight NC620) was used at 1 wt % relative to monomer.

### A-DCP:Ti-Initiator=100:1.7 wt %.

### A-DCP:N3B:IRT=100:0.06:0.08 wt %.

### Curing Conditions:

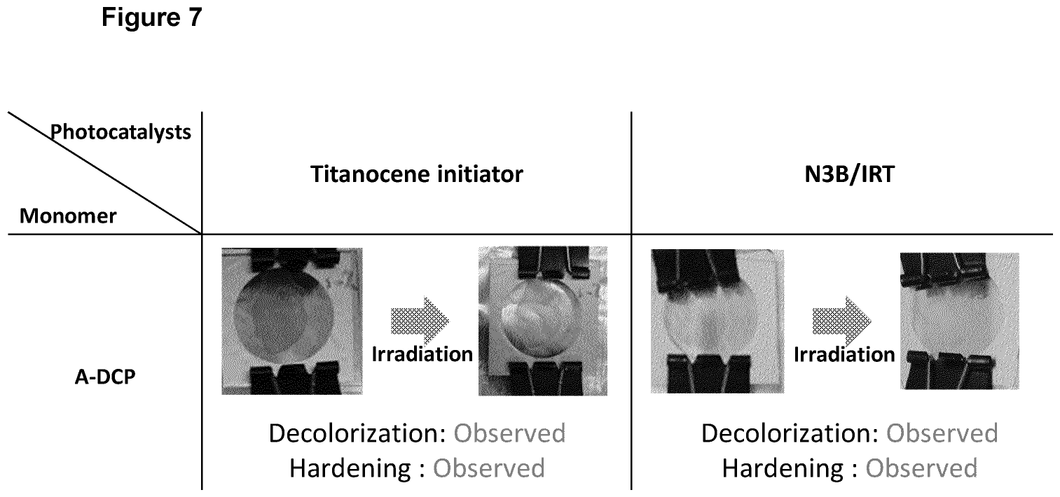

For titanocene initiator: Green LED, 40 mW/cm², 20 min, under air
For N3B/IRT: Red LED, 40 mw/cm², 10 min, under air
The A-DCP monomer/QD/photoinitator mixture was sealed between two glass plates and exposed to light. It was demonstrated that both exemplary photocatalytic systems work in the presence of 1 wt. % QDs (FIG. 7). Decolorization and hardening were also confirmed.

1. A composition comprising
(i) a monomer,
(ii) a photo initiator for photochemical polymerization of the monomer,
(iii) a sensitizer, and
(iv) quantum dots (QD)
for photochemical polymerization of quantum dot-based color conversion filter (QD-CCF) matrices and/or for matrix curing,
wherein the monomer (i) is represented by formula I 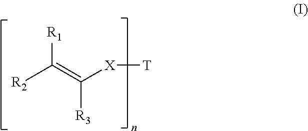
wherein
R₁ to R₃ are of the same, or each is independently selected from hydrogen or a C₁ to C₂₀ alkyl group,
T is selected from
a substituted or unsubstituted aliphatic hydrocarbon,
a substituted or unsubstituted aliphatic hydrocarbon wherein at least one methylene group is replaced with an ester group, an ether group, a carbonyl group, an amide group, or a combination thereof,
a substituted or unsubstituted alkylene oxide moiety, a substituted or unsubstituted polyalkylene oxide moiety,
a substituted or unsubstituted heterocyclic moiety,
a substituted or unsubstituted alicylic moiety,
a substituted or unsubstituted aromatic hydrocarbon group,
an organic siloxane moiety,
or a combination thereof,
X is an ester group (—C(═O)O—), a thiocarbonyl group (—S(═O)O—), an amide group (—C(═O)NH—), a carbonyl group, or a combination thereof,
n is 1 to 4.

2. The composition of claim 1, wherein the monomer (i) is represented by formulas Ia to Ic 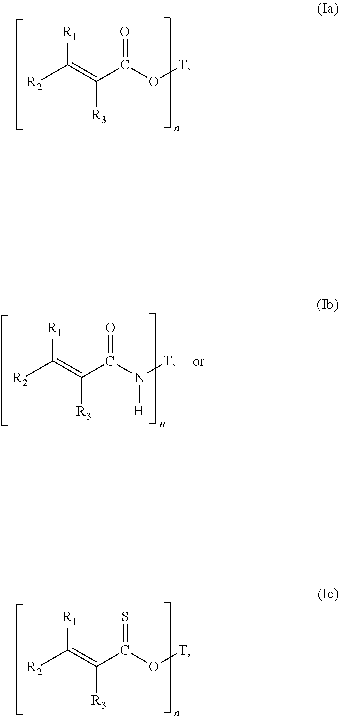
preferably Ia.

3. The composition of claim 1, wherein the monomer (i) is selected from 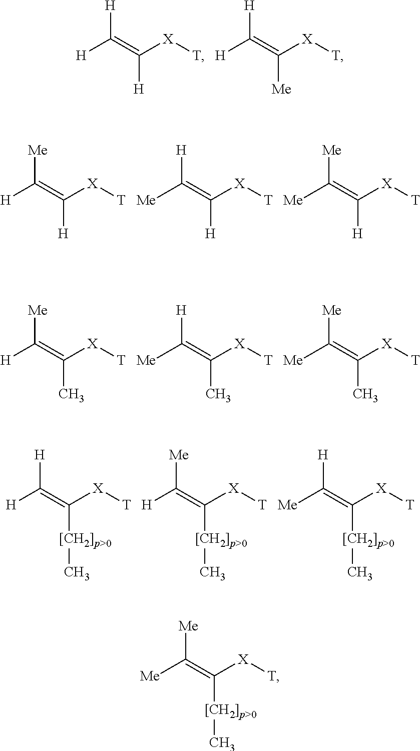
preferably

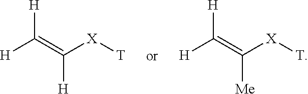

4. The composition of claim 1, wherein X is a carbonyl group 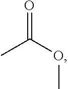
and the monomer (i) is a mono-functional monomer which is preferably selected from 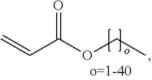
wherein o is 1 to 40, preferably 10 to 25, such as 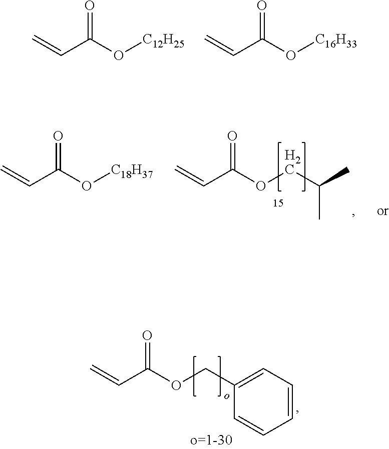
wherein o is 1 to 30, such as 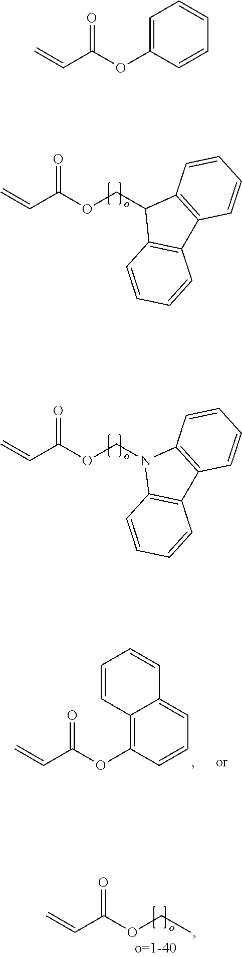
wherein o is 1 to 40, preferably 10 to 25, such as 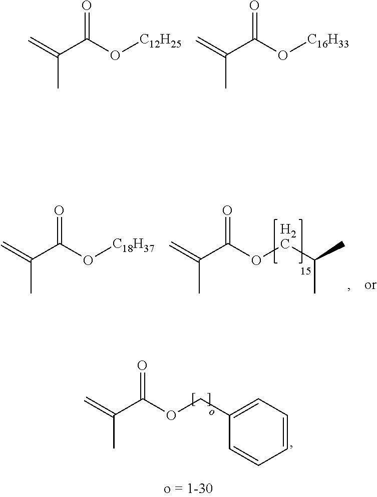
wherein o is 1 to 30, such as 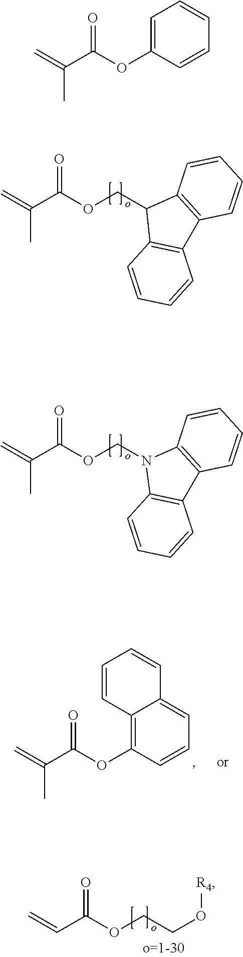
wherein o is 1 to 30 and R₄ is C₁ to C₁₀ alkylene group or C₁ to C₁₀-alkyl-phenylene group, such as 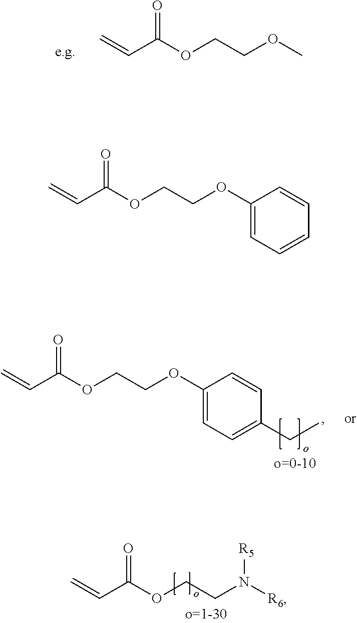
wherein o is 1 to 30 and R₅ and R₆ are the same or each independently selected from C₁ to C₁₀ alkylene group or can form a 6-membered ring, such as 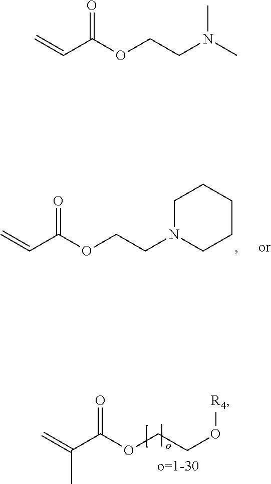
wherein o is 1 to 30 and R₄ is C₁ to C₁₀ alkylene group or C₁ to C₁₀-alkyl-phenylene group, such as 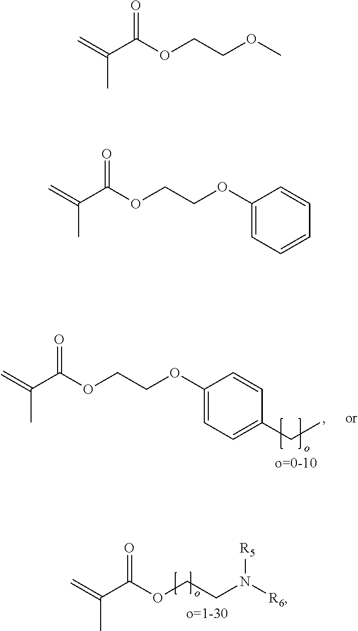
wherein o is 1 to 30 and R₅ and R₆ are the same or each independently selected from C₁ to C₁₀ alkylene group or can form a 6-membered ring, such as 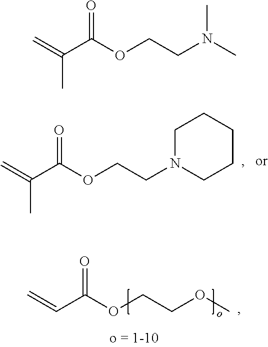
wherein o is 1 to 10, or 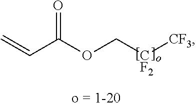
wherein o is 1 to 20, such as 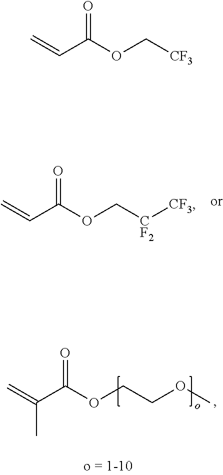
wherein o is 1 to 10, or 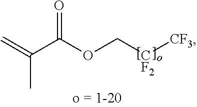
wherein o is 1 to 20, such as 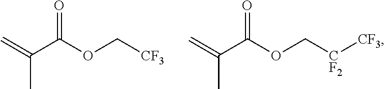
wherein the monomer is, for example, isostearyl acrylate (ISTA)

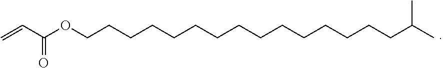 [SMILES: C=CC(=O)OCCCCCCCCCCCCCCCC(C)C]

5. The composition of claim 1, wherein the monomer (i) is a poly-functional monomer which is preferably selected from 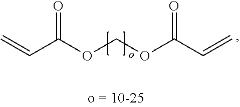
wherein o is 10 to 25, such as 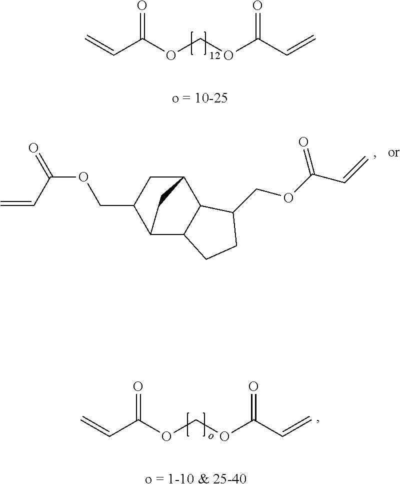
wherein o is 1 to 10 or 25 to 40, such as 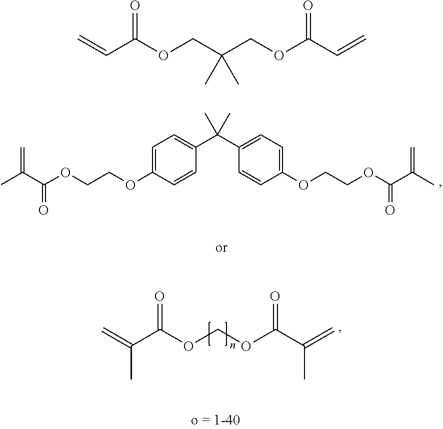
wherein o is 1 to 40, such as 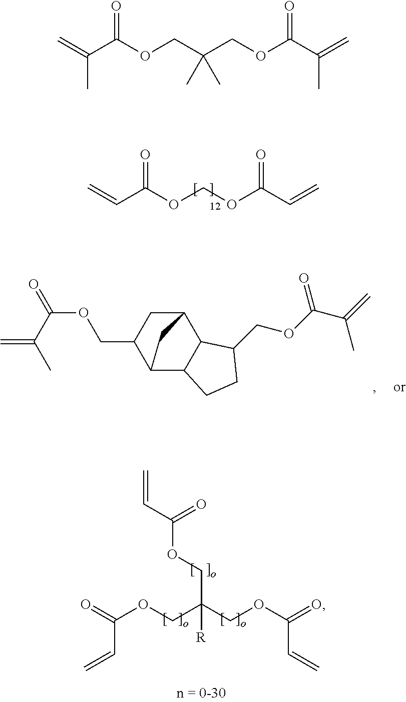
wherein o is 0 to 30, such as 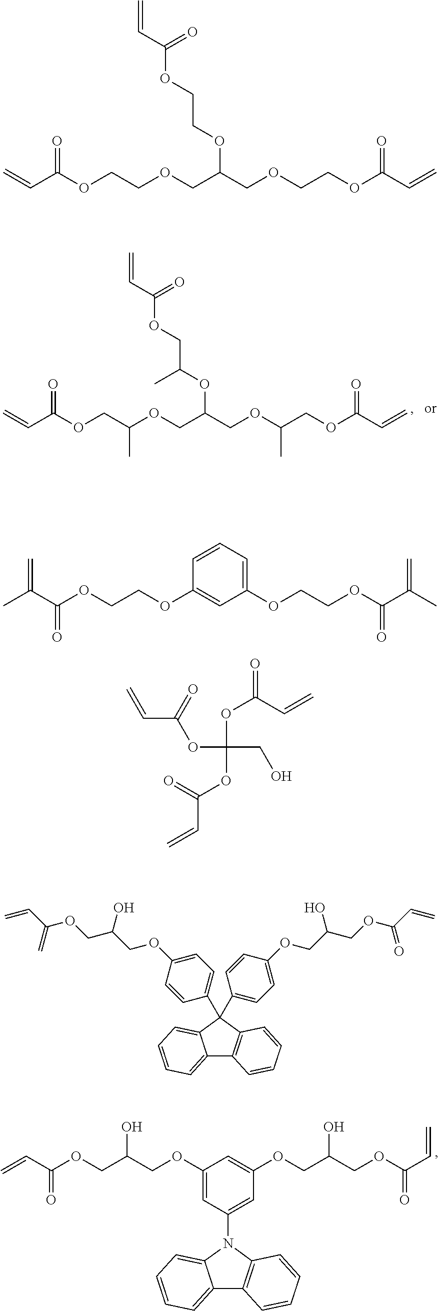
wherein the monomer is, for example, dicyclopentyldimethylene diacrylate (DDD) 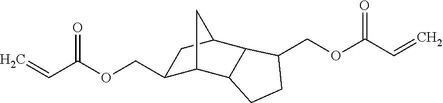 [SMILES: C=CC(=O)OCC1CC2CC1C1CCC(COC(=O)C=C)C21]
or 1,12-dodecanediol dimethacrylate (A-DCP)

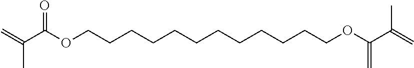 [SMILES: C=C(C)C(=C)OCCCCCCCCCCCCOC(=O)C(=C)C]

6. The composition of claim 1, wherein the sensitizer (iii) absorbs light which is transferred to the photo initiator (ii), wherein the sensitizer absorbs light preferably in a wavelength region of high transmittance of the QDs,
and/or wherein the sensitizer is selected (iii) from 1-{2,2-Bis[4-(diethylamino)phenyl]vinyl}-3,3-bis[4-(diethylamino)phenyl]propa-2-ene-1-ylium p-toluenesulfonate (IRT), Methylene blue, a merocyanine or a cyanine.

7. The composition of claim 1, wherein the photo initiator (ii) is Bis(cyclopentadienyl)bis(2,6-difluoro-3-(1H-pyrro; 1-(2,4-Difluorophenyl)-1H-pyrrole titanium complex (Ti-Initiator), Tetrabutylammonium-butyltrinaphthylborate (N3B) or Tetrabutylammonium-butyltriphenylborate (P3B).

8. The composition of claim 1, wherein the quantum dots (QDs) (iv) comprise elements of several groups of the periodic system, such as but not limited to:
type II/VI semiconductor materials,
such as CdS, CdSe, CdTe, ZnS, ZnSe, ZnTe, CdSe/ZnS, CdSe/CdS, CdSe/ZnSe, CdTe/CdS, CdTe/ZnS, CdTe/CdS/ZnS,
type III/V semiconductor materials,
such as InP, InAs, GaAs,
group IV-VI elements,
such as PbSe, PbS, PbTe,
group IB-(III)-VI elements,
such as CuInS₂, AgInS₂, Ag₂Se, Ag₂S; CuInZnS/ZnS,
group IV elements,
such as silicon QDs (Si QDs), carbon dots (C-dots), graphene QDs (GQDs).

9. The composition of claim 1,
wherein the quantum dots (iv) comprise polymerizable ligand(s) bound to their surface,
wherein a preferred polymerizable ligand is represented by formula II 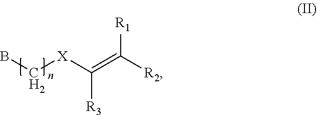
wherein
B is a carboxylic acid group, amine group, thiol group, phosphonic acid group,
X is ester group, a thiocarbonyl group, an amide group, or a combination thereof,
n being at least 1, such as 1 to 30, preferably 10 to 20, such as 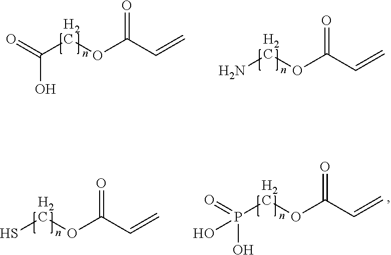
wherein said polymerizable ligand(s) are added during the polymerization or are a priori at the surface of the QDs.

10. A method for photochemical polymerization of quantum dot-based color conversion filter (QD-CCF) matrices and/or for matrix curing,
comprising the use of a combination of a sensitizer and a photo initiator, and comprising the use of a composition of claim 1.

11. The method of claim 10, comprising the steps
(1) providing the monomer,
(2) adding the sensitizer and the photo initiator,
(3) adding the QDs, preferably as a dispersion.
(4) coating the mixture onto a substrate,
(5) exposing to light which is in the absorbance range of the sensitizer.

12. The method of claim 11, wherein after the addition of sensitizer and the photo initiator follows a heating step and the mixture is shielded from light.

13. The method of claim 11, comprising thorough mixing after step (3).

14. The method of claim 10, comprising the use of QDs having polymerizable ligand(s) bound to their surface, preferably as defined in claim 9.

15. The method of claim 10, comprising the addition of polymerizable ligand(s) that bind to the surface of the QDs, wherein the polymerizable ligand(s) are preferably as defined in claim 9.

16. A thin layer, obtained with a method according to claim 10.

17. A thin layer, obtained by using the composition of claim 1.

18. The thin layer of claim 16, wherein the polymer is represented by formula III 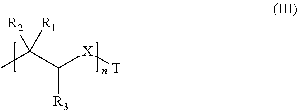
wherein
n is equal to or greater than 2.

19. A quantum dot-based color conversion filter (QD-CCF) matrix, comprising a thin layer of claim 16.

20. Use of the thin layer of claim 16 as quantum dot-based color conversion filter (QD-CCF).

21. A device, comprising a quantum dot-based color conversion filter (QD-CCF), comprising a thin layer of claim 16, wherein said device is preferably a micro LED array display, a micro LED display, a LED backlight display, a LCD display, a LED device, or a LED lighting device.
